(19) United States
(12) Patent Application Publication
(10) Pub. No.: US 2015/0162411 A1
(43) Pub. Date: Jun. 11, 2015

(54) METHOD OF MANUFACTURING A SEMICONDUCTOR STRUCTURE AND SEMICONDUCTOR STRUCTURE

(71) Applicant: Infineon Technologies AG, Neubiberg (DE)

(72) Inventors: Hans-Joachim Schulze, Taufkirchen (DE); Markus Zundel, Egmating (DE); Anton Mauder, Kolbermoor (DE); Andreas Meiser, Sauerlach (DE); Franz Hirler, Isen (DE); Hans Weber, Bayerisch Gmain (DE)

(73) Assignee: Infineon Technologies AG, Neubiberg (DE)

(21) Appl. No.: 14/101,378

(22) Filed: Dec. 10, 2013

(51) Int. Cl. H01L 29/40; H01L 21/768; H01L 29/78; H01L 21/265; H01L 29/66; H01L 21/02; H01L 21/225

(52) U.S. Cl. CPC H01L 29/407; H01L 21/0223; H01L 21/02258; H01L 21/76802; H01L 21/76877; H01L 21/02255; H01L 21/225; H01L 21/265; H01L 29/66477; H01L 29/78

(57) ABSTRACT

A method for manufacturing a semiconductor structure is provided, which may include: forming a p-doped region adjacent to an n-doped region in a substrate; carrying out an anodic oxidation to form an oxide layer on a surface of the substrate, wherein the oxide layer in a first portion of the surface extending along the n-doped region has a greater thickness than the oxide layer in a second portion of the surface extending along the p-doped region.

### TECHNICAL FIELD

Various embodiments relate generally to a method of manufacturing a semiconductor structure, and to a semiconductor structure.

### BACKGROUND

Modern power component cells are usually designed according to a trench concept, wherein the trench is arranged perpendicular to the chip surface. Thereby, the packaging density is increased, as well as the added value per unit silicon area.

Field-plate components represent a special type of trench cells. One characteristic of such a field-plate component is usually a relatively thick oxide structure (field oxide) in a lower part of a side wall of the trench, and a laterally adjacent poly-layer acting as a so-called field plate (field plate concept). A large part of equipotential lines are usually channeled through the oxide structure, which means that it contributes significantly at lowering a voltage between the source on a front side of a chip and a drain on a back side of the chip. A gate oxide, which usually is considerably thinner than the field oxide, usually adjoins the field oxide at the top. It is contacted on one side by the gate electrode usually made from polysilicon.

A conventional process for the manufacturing of such a component is shown in FIG. 15A to FIG. 15H. As shown FIG. 15A, a substrate 1702 is provided, wherein the substrate 1702 may be n⁺-doped. An n-doped region 1704 may be epitaxially grown on the n⁺-doped substrate 1702. At least one trench 1708 may be etched in the substrate and in the n-doped region using an oxide 1706 (for example formed from tetraethyl orthosilicate (TEOS) which is deposited above the n-doped region 1704) as a mask. In FIG. 15B, the trench etching is followed by a removal of the masking oxide 1706. Thereafter, an oxide layer 1710 is formed over all exposed surfaces. Then, the trench 1708 is completely filled up with a layer of polysilicon 1712. As shown in FIG. 15C, the polysilicon 1712 is etched back using a further mask 1714. A wedge of polysilicon 1712 thus remains in a lower portion of the trench 1708, which will form a field plate at source potential. In FIG. 15D, the mask 1714 will be removed and a gate mask 1716 is formed. Then, exposed parts of the oxide layer 1710 are removed, leaving a portion of the oxide layer 1710 that will form the field oxide. In FIG. 15E, after removal of the gate mask 1716, a gate oxide 1718 is formed. Subsequently, a polysilicon gate 1720 is deposited and etched using a yet further mask 1722. As shown in FIG. 15F, the mask 1722 will then be removed, and an oxide layer 1730 is deposited, and a body region 1724, a source region 1726 and source contacts 1728 will be formed. In FIG. 15G, the oxide layer 1730 is etched, followed by a formation of a gate silicide 1732, a deposition of a glass layer 1734, and etching of trenches 1736. Then, body contacts 1738 are implanted and metal contacts 1740 are formed. In FIG. 15H, polysilicon is deposited and etched to form plugs 1742. Finally, a metal layer structure is formed and etched to form the source contact 1744 and the gate contact 1746.

This conventional process may result in a field oxide structure wherein a field oxide base point (an upper edge of the field oxide structure) is determined by an upper edge of the field plate (field plate base point), because the field plate serves as a kind of mask during an etching of the field oxide. This means that a position of a body region is not directly linked to the field plate base point, because the poly recess etching process mostly determines the field plate base point. Consequently, a distance (XGD) between a lower edge of the p-doped body-/channel region and the field plate base point may be determined by relative large fluctuations of at least this one process. During a later process, ions (boron) forming a doping of the body are implanted into a whole surface of mesa areas (mesa being a vertical structure formed in the semiconductor device by forming trenches in two positions near each other, leaving a pillar- or wall-like structure—the mesa—between them). Then the body is formed via thermal outdiffusion. The outdiffusion cannot be limited by the position of the field plate base point. However, the lower edge of the body should not be located as low as to reach the field oxide area, because an increased effective gate oxide thickness would increase a turn-on resistance. This means that a production tolerance is usually introduced.

The field plate component was usually optimized for short switching intervals, requiring a gate-/drain capacity that is as low as possible, with a goal of reducing/eliminating a so-called Miller-plateau. This capacity is mainly determined by XGD (a source-/drain capacity has a lower impact on switching speed, therefore a lower poly electrode is set to source potential). This means that an optimization of component performance may require a minimization of XGD.

### SUMMARY

A method for manufacturing a semiconductor structure is provided, which may include: forming a p-doped region adjacent to an n-doped region in a substrate; carrying out an anodic oxidation to form an oxide layer on a surface of the substrate, wherein the oxide layer in a first portion of the surface extending along the n-doped region has a greater thickness than the oxide layer in a second portion of the surface extending along the p-doped region.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A to FIG. 1O show a process flow for a method for manufacturing a semiconductor structure in accordance with various embodiments;

FIG. 2 shows a semiconductor structure in accordance with various embodiments;

FIG. 3 shows a semiconductor structure in accordance with various embodiments;

FIG. 4A and FIG. 4B show semiconductor structures in accordance with various embodiments;

FIG. 5A to FIG. 5C show three stages of a process flow for a method for manufacturing a semiconductor structure in accordance with various embodiments;

FIG. 6A and FIG. 6B show two stages of a process flow for a method for manufacturing a semiconductor structure in accordance with various embodiments;

FIG. 7A to FIG. 7C show three stages of a process flow for a method for manufacturing a semiconductor structure in accordance with various embodiments;

FIG. 8 shows a semiconductor structure in accordance with various embodiments;

FIG. 9 shows a schematic diagram of a method of manufacturing a semiconductor structure in accordance with various embodiments;

FIG. 10 shows a schematic diagram of a method of manufacturing a semiconductor structure in accordance with various embodiments;

FIG. 11A and FIG. 11B show a schematic for a principle setup for anodic oxidation and a graph of a measurement of a leakage current of a via with 200 nm oxide deposited via plasma enhanced chemical vapor deposition (PECVD) and 50 nm anodic oxide in accordance with various embodiments;

FIG. 12 shows a graph of an etching rate as a function of boron doping for different concentrations of KOH in accordance with various embodiments;

FIG. 13 shows a graph of a field strength component vertical to a trench wall as a function of a vertical coordinate z in accordance with various embodiments;

FIG. 14 shows a graph of a horizontal component of an electrical field strength as a function of a lateral coordinate x in accordance with various embodiments; and

FIG. 15A to FIG. 15H show a process flow for a method for manufacturing a semiconductor structure in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

In like manner, the word “cover”, used herein to describe a feature disposed over another, e.g. a layer “covering” a side or surface, may be used to mean that the feature, e.g. the layer, may be disposed over, and in direct contact with, the implied side or surface. The word “cover”, used herein to describe a feature disposed over another, e.g. a layer “covering” a side or surface, may be used to mean that the feature, e.g. the layer, may be disposed over, and in indirect contact with, the implied side or surface with one or more additional layers being arranged between the implied side or surface and the covering layer.

Directional terminology, such as e.g. “upper”, “lower”, “top”, “bottom”, “left-hand”, “right-hand”, etc., may be used with reference to the orientation of figure(s) being described. Because components of the figure(s) may be positioned in a number of different orientations, the directional terminology is used for purposes of illustration and is in no way limiting. It is to be understood that structural or logical changes may be made without departing from the scope of the invention.

Various embodiments provide a manufacturing method for a semiconductor structure that allows to exactly configure the overlap XGD, and to thereby minimize it, even in a self-adjusting manner.

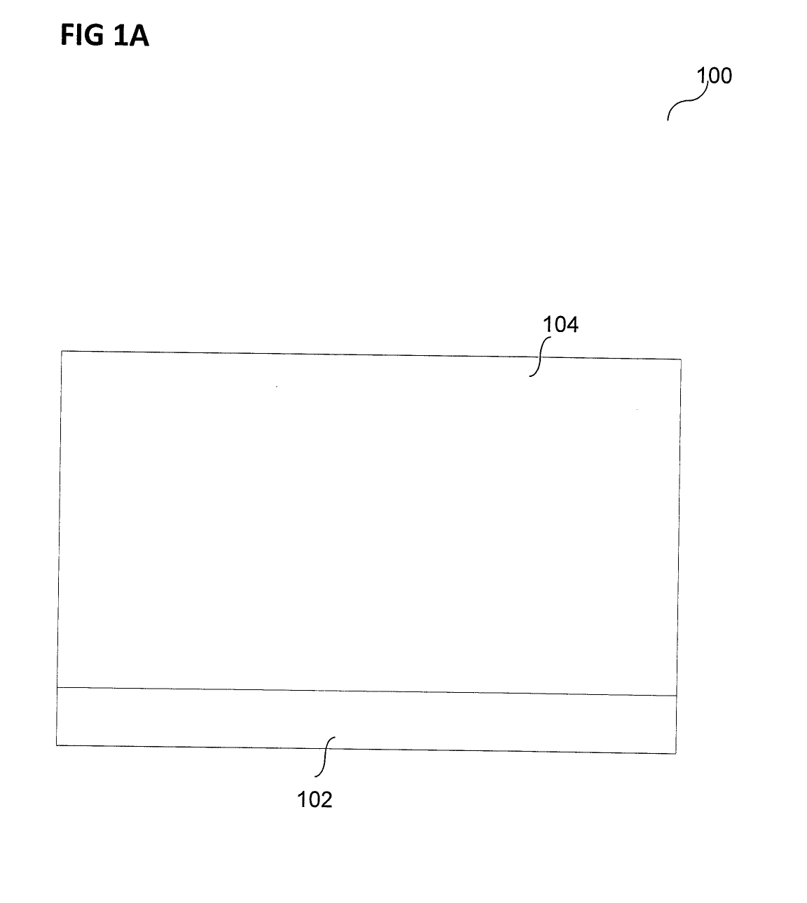

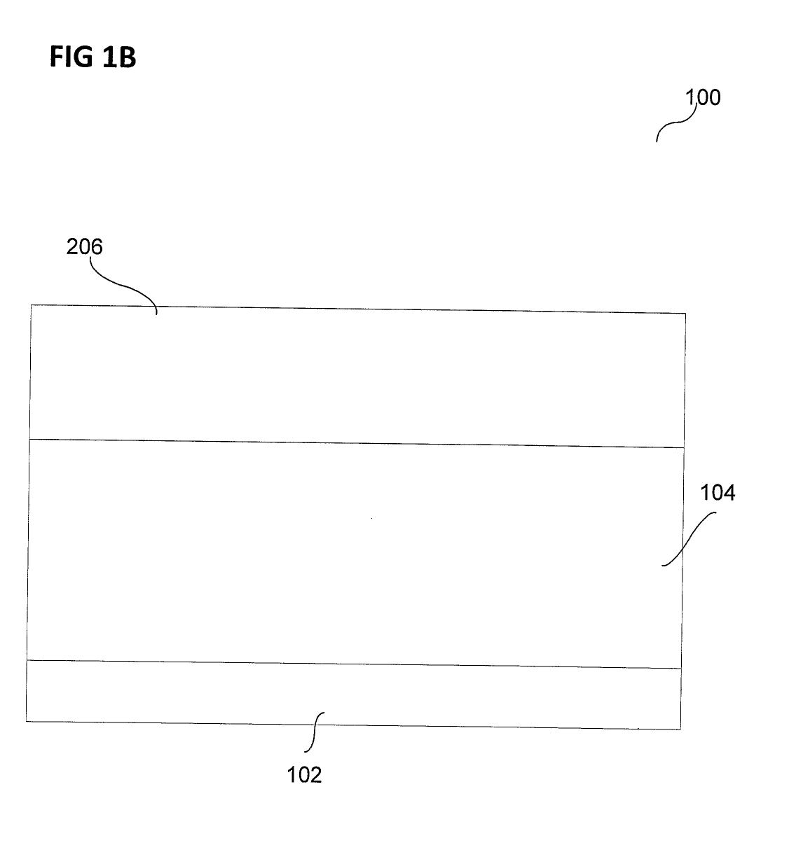

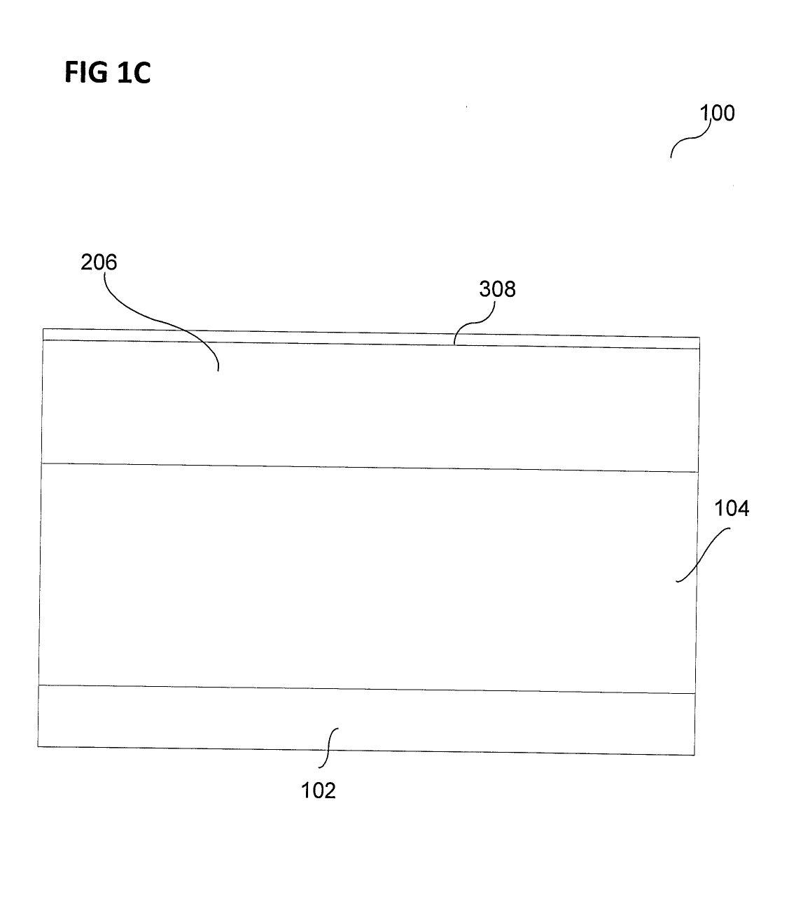

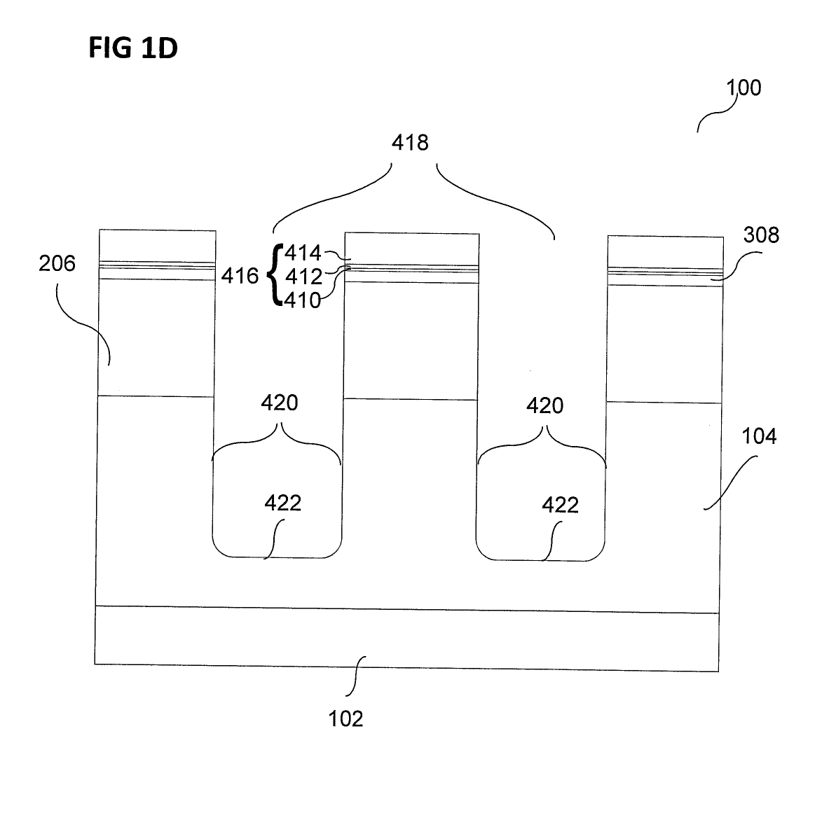

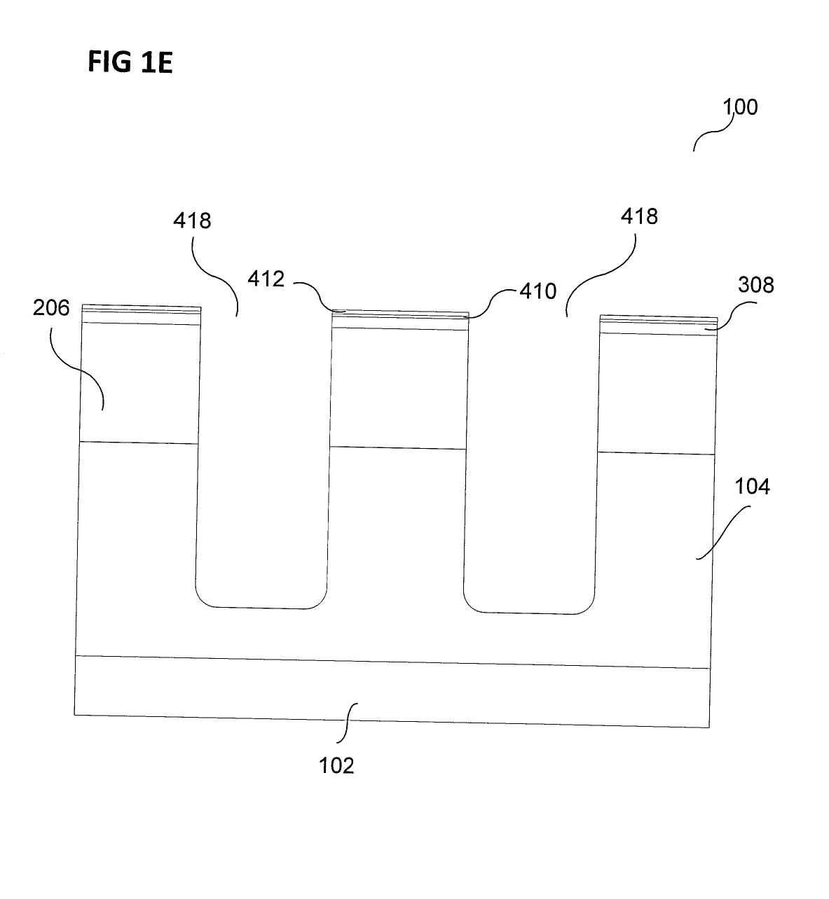

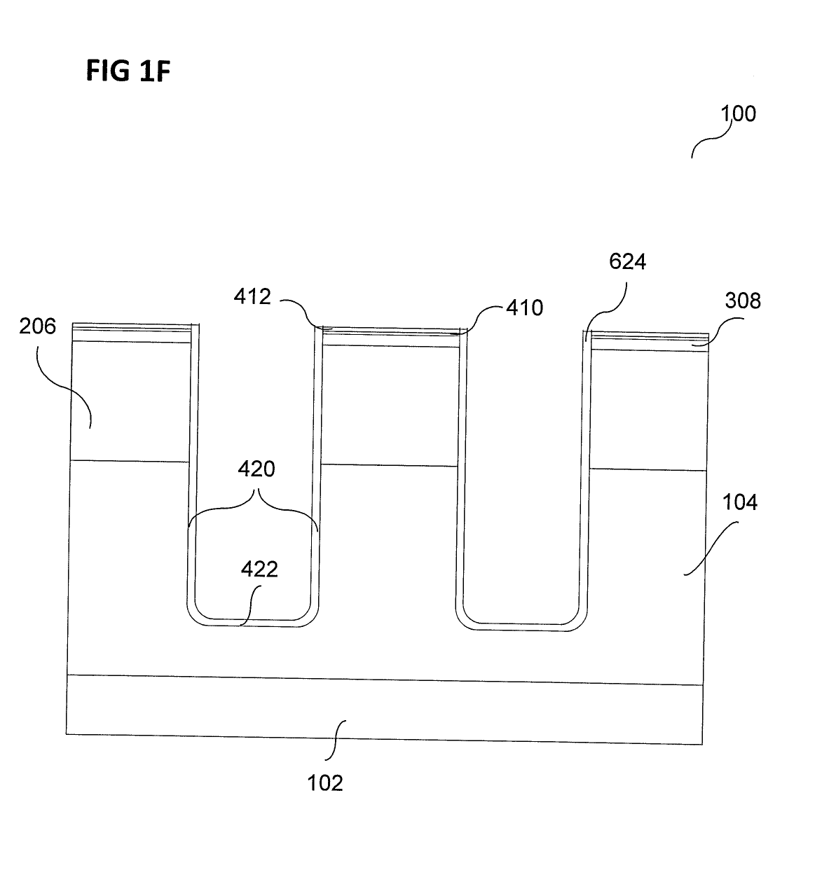

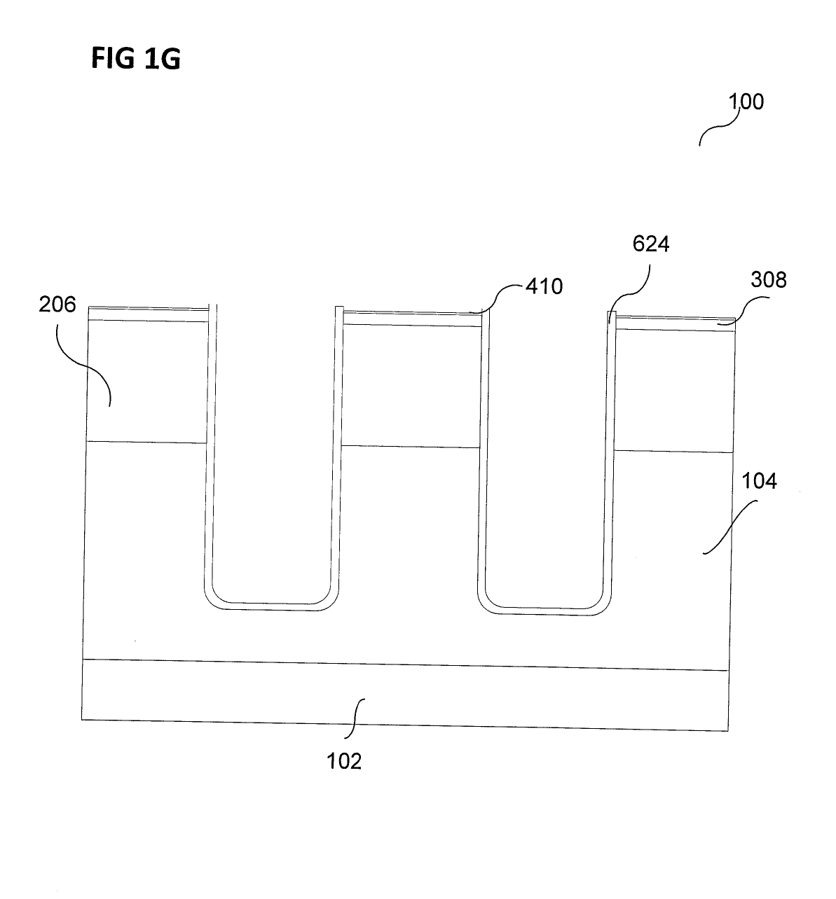

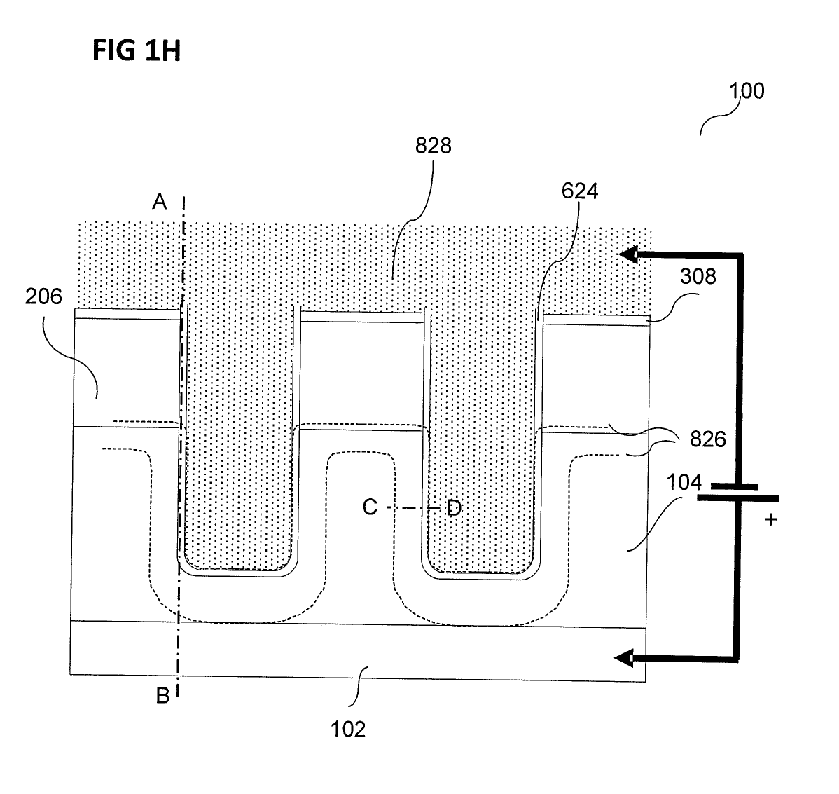

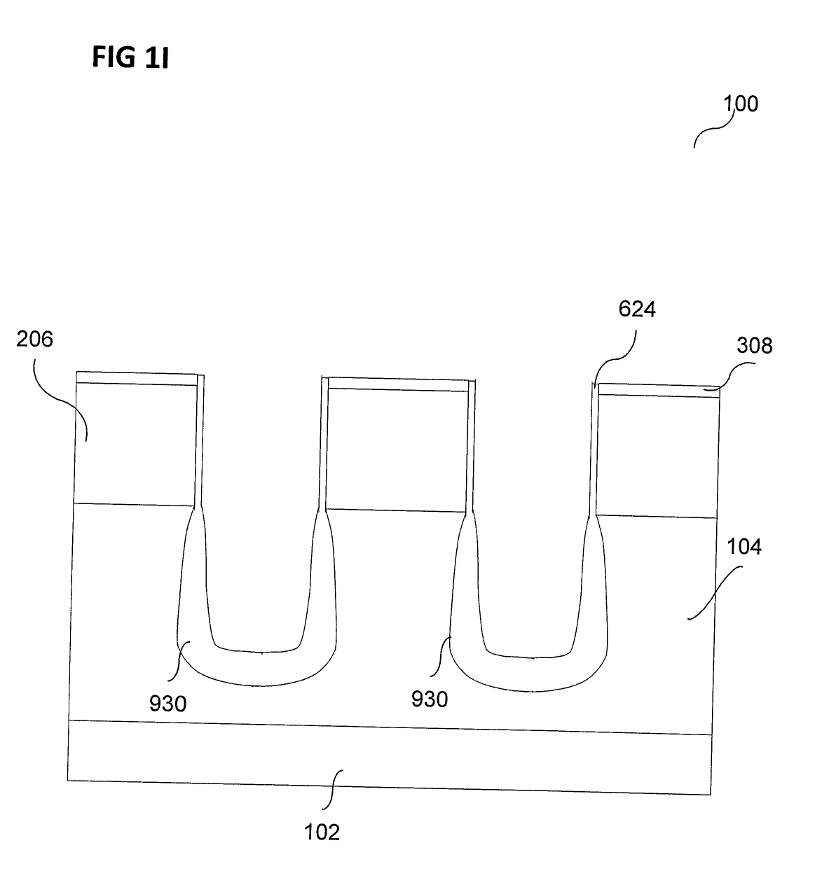

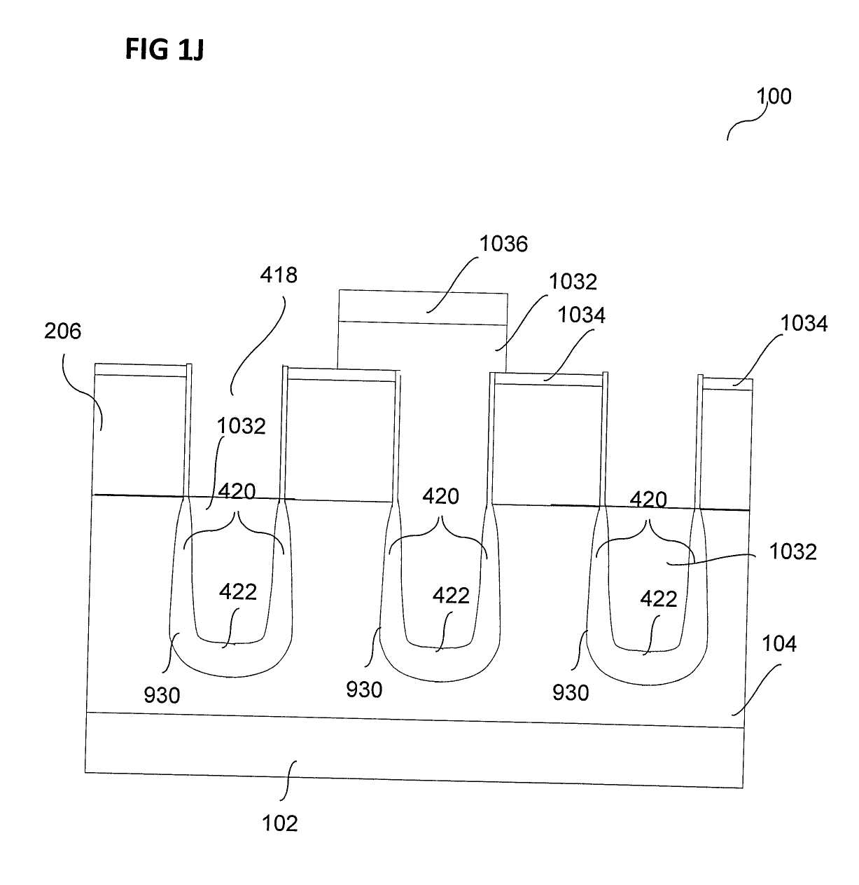

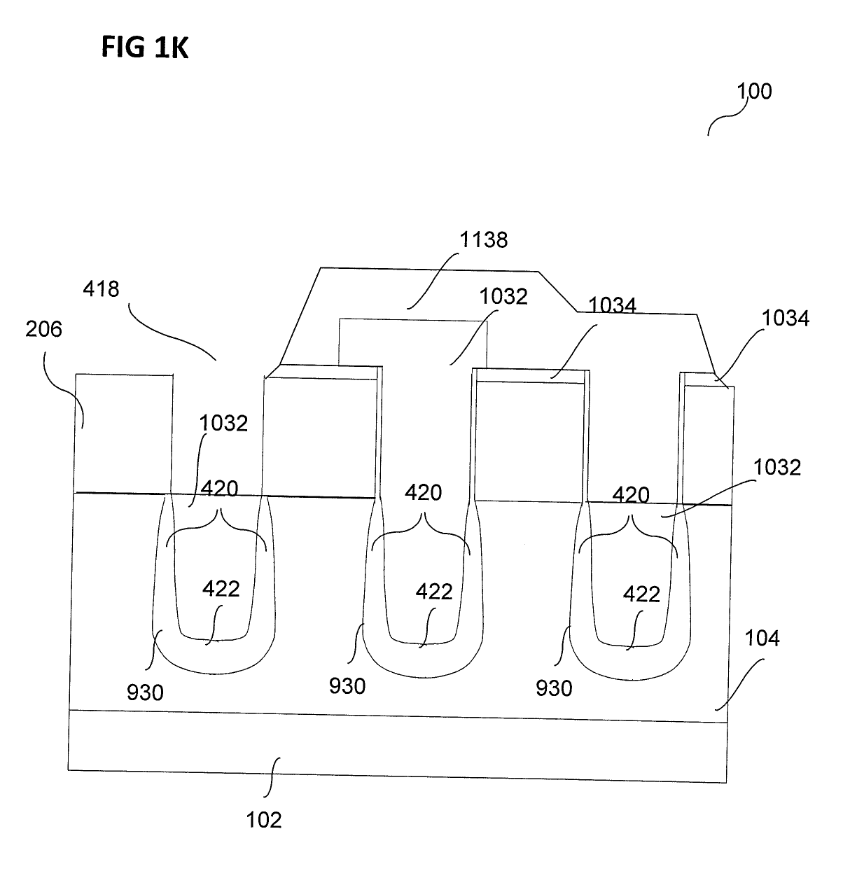

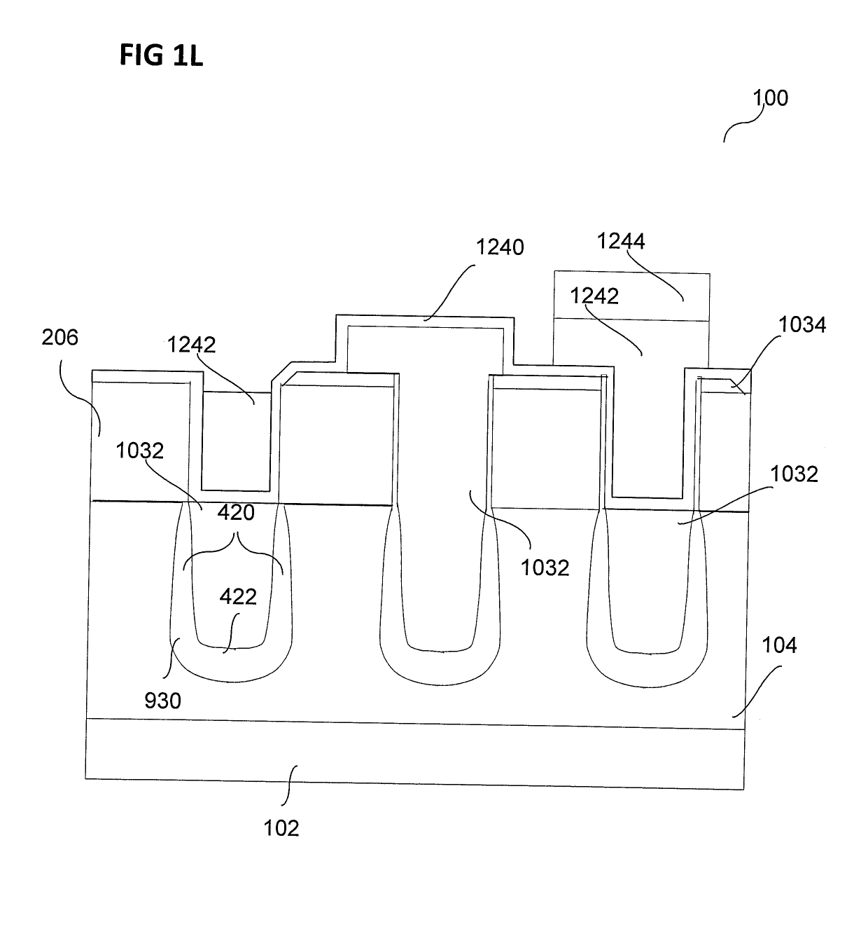

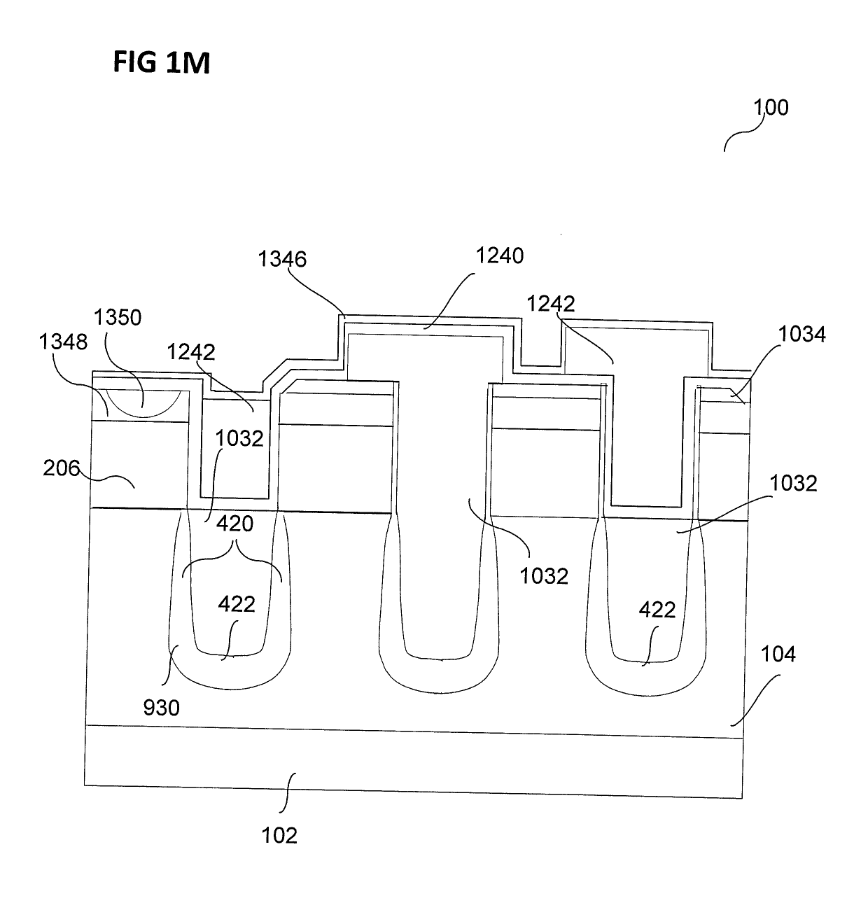

Various embodiments adjust a process flow for manufacturing a semiconductor structureand an anodic oxidization method with respect to each other in such a way that the oxide side wall of an open trench in a region of an n-doped epitaxial layer is oxidized faster than in the p-doped region, and that consequently a thicker oxide layer is formed in the region of the n-doped epitaxial layer than in the p-doped region. For using the selective oxidization of a field plate component for a minimization of XGD which would optimize the corresponding capacity C_{GD}, a process modification that results in a cross section of a semiconductor structureas shown in FIG. 1H may be used. FIG. 1H shows the situation at the time of anodic oxidation, wherein the dashed lines represent borders of space-charge regions, and wherein V_{aO} may be below a mesa depletion voltage.

This means that the oxidization of the side wall in a trench happens quasi selectively according to the doping conditions in the mesa, and this process will be used for the definition or the formation of a field oxide for a field-plate component.

FIG. 1A to FIG. 1I show a process flow for a method for manufacturing a semiconductor structure 100 according to various embodiments.

As shown in FIG. 1A, the method for manufacturing a semiconductor structure 100 may include forming an n-doped (target doped) region 104 over an n⁺-doped substrate region 102. The substrate may include, or may consist of, a semiconductor material. The semiconductor material may include, or may be silicon, although other materials may be possible as well. In various embodiments, the substrate may be n⁺-doped.

In various embodiments, the thickness of the substrate may be smaller than 1 mm, for example smaller than or equal to 800 μm, for example in the range from about 700 μm to about 800 μm, or for example in the range from about 200 μm to about 700 μm, or for example in the range from about 3 μm to about 200 μm, for example in the range from about 3 μm to about 10 μm.

In various embodiments, the electrical resistivity of the substrate may be smaller than or equal to about 10⁻⁴ Ω·m, for example smaller than or equal to about 5·10⁻⁵ Ω·m, for example in the range from about 1·10⁻⁵ Ω·m to about 3·10⁻⁵ Ω·m.

In various embodiments, the electrical resistivity of the substrate may be higher than or equal to about 10⁻⁴ Ω·m, or for example higher than or equal to about 1·10⁻⁵ Ω·m, for example in the range from about 1·10⁻⁵ Ω·m to about 2·10⁻⁵ Ω·m.

Forming the n− and n+-doped regions may be performed by various techniques and include, without being limited thereto, the useage of initially doped substrate or of diffusion or implantation of doping materials into the substrate material, wherein said doping materials may be selected from the group of P, As, Sb, and/or Bi, for an n− and/or an n⁺-doping. The techniques may further include deposition of a doped layer, for example epitaxial deposition, via printing, plating, such as plating deposition, dip-coating, spray-coating, powder-coating and/or vapor deposition, including chemical vapor deposition (CVD) and physical vapour deposition (PVD). The printing may, for example, be screen-printing or extrusion-printing.

In various embodiments, the thickness of the n-doped region may be smaller than or equal to about 100 μm, for example smaller than or equal to about 50 μm, for example smaller than or equal to about 10 μm, for example in the range from about 5 μm to about 7 μm, or for example in the range from about 2 μm to about 5 μm.

In various embodiments, the doping concentration of the n-doped region may be smaller than or equal to about 10¹⁸ cm⁻³, for example smaller than or equal to about 10¹⁷ cm³, for example in the range from about 10¹⁶ cm⁻³ to about 10¹⁷ cm⁻³, for example in the range from about 4·10¹⁶ cm⁻³ to about 6·10¹⁶ cm⁻³. In various embodiments, the n-doped region 1704 may be epitaxially grown on the n⁺-doped region 1702, for example with a doping concentration of about 5·10¹⁶ cm³, a thickness of about 6 μm and an electrical resistivity of about 1.51·10³ Ω·m.

As shown in FIG. 1B, the method for manufacturing a semiconductor structure 100 may include forming a p-doped region 206 over the n-doped region 104. Forming the p-doped region may be performed by various techniques and may include, without being limited thereto, the diffusion or implantation of doping materials into the n-doped region, wherein said doping materials may be selected from the group of B, Al, Ga, In, and/or Tl for a p-doping. The techniques may further include deposition of a doped layer, for example epitaxial deposition, for example via printing, plating, such as plating deposition, dip-coating, spray-coating, powder-coating and/or vapor deposition, including chemical vapor deposition (CVD) and physical vapor deposition (PVD). The printing may, for example, be screen-printing or extrusion-printing.

In various embodiments, the formation of the p-doped region may include the implantation of ions with an ion energy of less than or equal to about 500 keV, for example less than or equal to about 100 keV, for example in the range from about 10 keV to about 100 keV, for example in the range from about 50 keV to about 70 keV. In various embodiments, boron ions may be used for the implantation.

In various embodiments, the formation of the p-doped region may include the implantation of ions with an implant dose of less than or equal to about 10¹⁶ cm⁻², for example less than or equal to about 10¹⁵ cm⁻², for example in the range from about 10¹² cm⁻² to about 10¹⁵ cm⁻², for example in the range from about 10¹³ cm⁻² to about 3·10¹³ cm⁻², for example with an implant dose of about 10¹³ cm⁻².

In various embodiments, the doping concentration of the p-doped region may be smaller than or equal to about 10¹⁸ cm⁻³, for example in the range from about 5·10¹⁶ cm⁻³ to about 5·10¹⁷ cm³, for example about 10¹⁷ cm⁻³.

In various embodiments, the formation of the p-doped region may additionally or alternatively include a process of diffusing ions, for example from a gaseous source or from a solid source, into the n-doped region, for example by means of heating, wherein the heating temperature may for example be above 1000° C., for example for a duration of more than 60 minutes.

As shown in FIG. 1C, the method for manufacturing a semiconductor structure 100 may include forming a p⁺⁺-doped region 308 over the p-doped region 206. The formation of the p⁺⁺-doped region 308 may be performed by various techniques and may include, without being limited thereto, the diffusion or implantation of doping materials into the substrate material, wherein the doping materials may be selected from the group of B, Al, Ga, In, and/or Tl for a p⁺⁺-doping. The techniques may further include deposition of a doped layer, for example via printing, plating, such as plating deposition, dip-coating, spray-coating, powder-coating and/or vapor deposition, including chemical vapor deposition (CVD) and physical vapour deposition (PVD). The printing may, for example, be screen-printing or extrusion-printing.

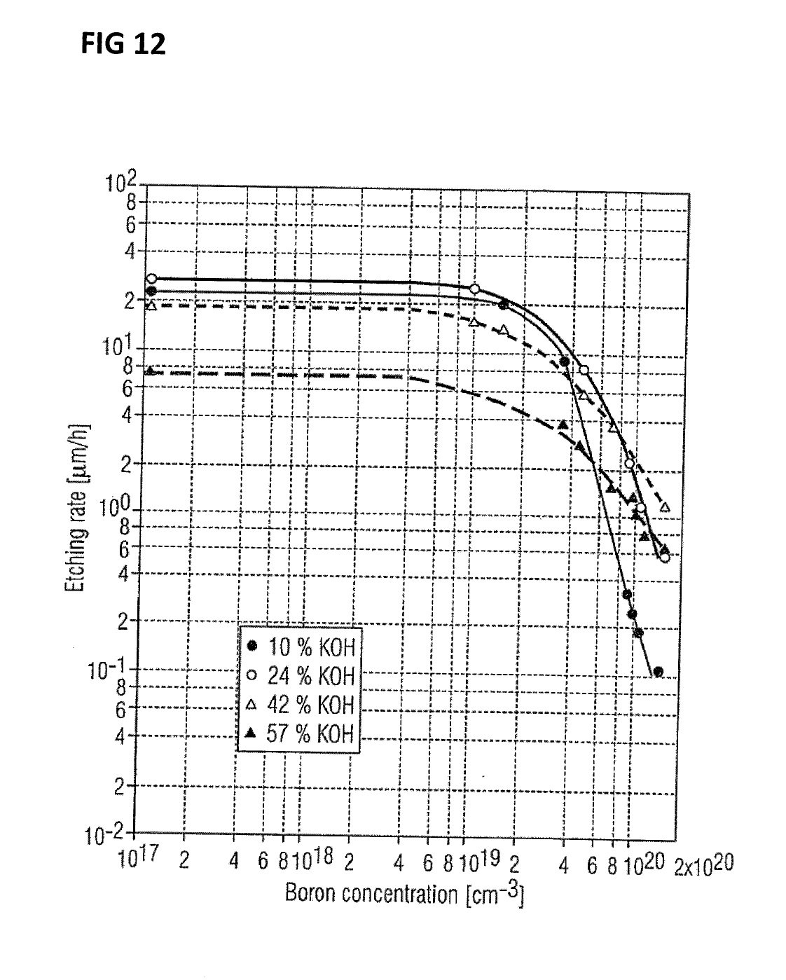

Even though alkaline solutions are usually highly inert with respect to oxides, they will etch a semiconductor with a high etching rate if they are in direct contact with it. This may be avoided if the doping concentration in the p⁺⁺-doped region 308 is sufficiently high (see e.g. FIG. 12 showing a dependence of etching rate on boron doping concentration). In various embodiments, the doping concentration in the p⁺⁺-doped region 308 may therefore be above or equal to about 10¹⁹ cm⁻³, for example in the range from about 4·10¹⁹ cm³ to about 3·10²⁰ cm⁻³, for example in the range from about 7·10¹⁹ cm⁻³ to about 2·10²⁰ cm³, in order to avoid an etching of the p⁺⁺-doped region 308 during the anodic alkaline oxidization which will be described in more detail below. These doping concentrations may for example be obtained by implantation of ions with an implant dose of more than or equal to about 10¹⁵ cm⁻².

In various embodiments, the formation of the p⁺⁺-doped region may further include a process of annealing the p⁺⁺-doped region 308. The annealing may for example be performed via thermal annealing.

As shown in FIG. 1D, the method for manufacturing a semiconductor structure 100 may further include forming a mask 416 over or on the p⁺⁺-doped region 308, and forming at least one trench 418 in the substrate, the trench 418 extending through the p-doped region 206 into the n-doped region 104.

In various embodiments, forming a mask may include forming at least one masking layer 416 on the p⁺⁺-doped region 308, forming a photoresist layer (not shown) on the masking layer 416, exposing regions of the photoresist layer using a trench photomask, removing the exposed regions of the photoresist layer, and removing the masking layer 416 in the areas where the photoresist layer was removed. In various embodiments, the forming of the at least one masking layer 416 may include or consist of forming a stack of a plurality of layers 410, 412, 414 including or consisting of a bottom oxide layer 410, a nitride layer 412, and a top oxide layer 414. In various embodiments, the bottom oxide layer 410 and the top oxide layer 414 may include or consist of SiO₂, and the nitride layer 412 may include or consist of Si₃N₄. In various embodiments, the masking layers 410, 412, 414 may have a thickness for example in the range from about 10 nm to about 200 nm, for example in the range from about 10 nm to about 50 nm. In various embodiments, forming the mask 416 may be followed by a removal of the remaining photoresist. In various embodiments, forming at least one trench 418 may include etching a trench 418 by various etching techniques. The etching techniques may include, without being limited thereto, plasma etching and dry etching. In various embodiments, the trench 418 may have a depth of about 2.2 μm and an end width of about 0.75 μm. In a further process, the trench 418 corners may be rounded using plasma etching.

As shown in FIG. 1E, the method for manufacturing a semiconductor structure 100 may include removing the top oxide layer 414. Removing the top oxide layer 414 may include, without being restricted thereto, wet chemical removal of the top oxide layer 414 using an oxide removal process. The oxide removal process may be, without being restricted thereto, a wet etching process, for example, without being restricted thereto, using HF as an etchant.

As shown in FIG. 1F, the method for manufacturing a semiconductor structure 100 may include a formation of an oxide layer 624. In various embodiments, formation of the oxide layer 624 may be performed via an oxidation, for example via thermal oxidation or via plasma oxidation, thereby forming an oxide layer 624 in the trench 418, but not on the nitride layer 412, wherein the oxide layer 624 may be formed essentially uniformly inside the trench 418, covering exposed surfaces of both the p-doped region 206 through which the trench 418 extends, and the n-doped region 104 into which the trench 418 extends. The oxide layer 624 may form a protection layer protecting the p-doped region 206 and the n-doped region 104 from being etched by the base used for an anodic alkaline oxidation performed in a later process. In various embodiments, the oxide layer may have a thickness in the range from about 10 nm to about 50 nm, for example in the range from about 20 nm to about 40 nm. In various embodiments, thermal oxidation may be performed at a temperature in the range from about 860° C. to about 1100° C., for example in the range from about 900° C. to about 1050° C.

In various embodiments, formation of the oxide layer 624 may be performed by removing the top oxide layer 414, followed by a thermal oxidation resulting in oxide layer 624, which may be thicker than oxide layer 410. During the oxidation, the nitride layer 412 may protect the mesa from further oxidation. Thereafter, the nitride layer 412 may be removed, followed by an etching process using HF to remove the oxide layer 410. If the oxide layer 410 is thinner than the oxide layer 624, it is possible to remove the oxide layer 410 completely from the top of the mesa, whereas the trench side walls 420 are still covered by the oxide layer 624 or parts thereof.

As shown in FIG. 1G, the method for manufacturing a semiconductor structure 100 may include a removal of the nitride layer 412. In various embodiments, the removal of the nitride layer 412 may be performed for example by means of wet chemically removing the nitride layer 412. In various embodiments, the bottom oxide layer 410 may be removed after the removal of the nitride layer 412 has been completed. In various embodiments, the bottom oxide layer 410 may be removed using oxide removal techniques, for example by means of a wet etching process, for example by means of wet etching using dipping the bottom oxide layer 410 of the semiconductor structure 100 into an etchant, for example HF. In various embodiments, the oxide layer 624 on the trench side walls 420 is not removed, or only partially removed in such a way that the trench side walls 420 are still covered by oxide.

As shown in FIG. 1H, the method for manufacturing a semiconductor structure 100 may include an anodic alkaline oxidation. The at least one trench 418 may be filled with an alkaline or basic liquid, such that the trench 418 and the p⁺⁺-doped region 308 may be in physical contact with the alkaline solution 828. The alkaline solution may for example include KOH, TMAH or KNO₃, or more generally any alkaline solution supplying OH⁻ ions. This arrangement means that a direct electrical contact between the alkaline solution 828 and the mesa surface, i.e. the surfaces of the p-doped region 206 and the n-doped region 104 underneath the oxide layer 624, may be provided via the p⁺⁺-doped region 308, where the potential that the alkaline solution 828 is set to (ground potential) is coupled into the p-doped region. A back side of the semiconductor structure 100 may be set to positive potential V_{aO} via a chuck (not shown). This means that the p-n junction formed by the p-doped region 206 and the n-doped region 104 is reverse biased. A Schottky diode forms at the transition of semiconductor 100 and alkaline solution 828, the alkaline solution 828 representing an electrolyte. Due to the p⁺⁺-doping of the upper side of the mesa in the p⁺⁺-doped region 308, the Schottky diode is degenerated, which means that the p-doped region is not floating, but is set to ground voltage (apart from the built-in voltage). Consequently, this construction allows to contact the front side directly via the electrolyte (the alkaline solution 828), making a cumbersome and error prone needle contact obsolete. An etching of the p⁺⁺-doped region 308 by the alkaline solution 828 may be avoided by selecting a p⁺⁺-doping concentration that is sufficiently high (degenerate doping concentration) to provide an etch stop. In this way, it is rather uncritical when the semiconductor structure 100 is removed from the alkaline solution 828. FIG. 12 shows the dependence of etching rate on boron doping concentration for an electrolyte including different concentrations of KOH.

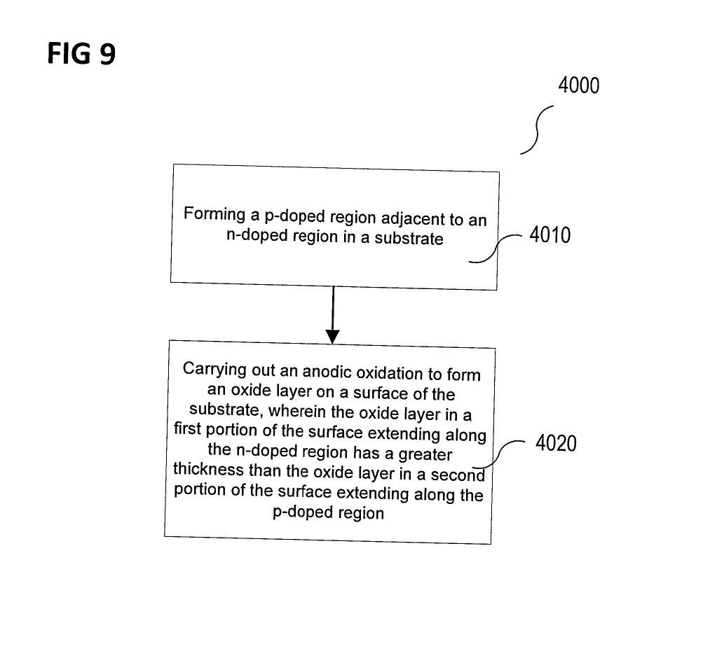

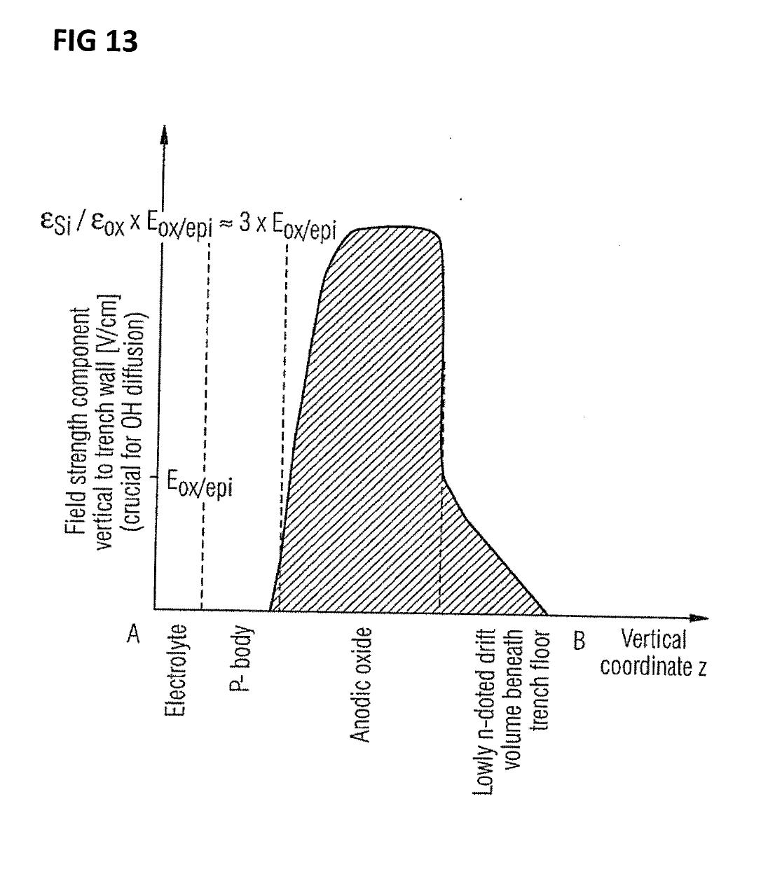

The p-n junction formed by the p-doped region 206 and the n-doped region 104 that may be reverse biased by the voltages of 0V and Vₐₒ that may be applied to the alkaline solution 828 and the backside of the semiconductor structure 100, respectively, causes the voltage difference between 0V and V_{aO}, i.e. the applied voltage, to be present in vertical direction at the p-n junction. This means that a side wall 420 of the trench 418, in the region of the p-doped region 206, may be field free (see FIG. 13, showing a graph of a field strength component vertical to a trench wall 420 as a function of a vertical coordinate z, wherein the vertical coordinate z is running from point A to point B in the cut indicated by the dash-dotted line in FIG. 1H, and compare also the structure of the space-charge region, the borders of which are indicated by dashed lines 826 in FIG. 1H). This is different in the region of the drift volume, i.e. the part of the n-doped region 104 near the trench side wall 420, because the full reverse voltage, i.e. the applied voltage, in horizontal direction, is present in the part of the oxide 624 that is located on the n-doped region 104 and in the adjoining region of the n-doped region 104 of the semiconductor structure 100. See also FIG. 9, showing a graph of a horizontal component of an electrical field strength as a function of a lateral coordinate x, wherein the lateral coordinate x extends from point C to point D in the cut indicated by the dash-dotted line in FIG. 1H. An elevated electric field 3 E_{ox/epi} is formed at the interface of the electrolyte 828 and the oxide layer 624. This causes a field-driven diffusion of OH⁻-ions from the alkaline solution (electrolyte) 828 through the already present oxide layer 624 into the surface of the n-doped region 104, where they react with the silicon to form SiO₂. The field-driven diffusion of OH⁻-ions and therefore the formation of SiO₂ only occurring in the region where the electrical field is strong, i.e. in the vertical direction essentially only in the region of the n-doped region 104, and not in the region of the p-doped region 206, results in an oxide layer 930 that has a greater thickness in a first portion of the trench 418 extending into the n-doped region 104 than in a second portion of the trench 418 extending through the p-doped region 206.

This means that the anodic alkaline oxidation is illustratively used to adjust or minimize the distance between the lower edge of the p-doped body-/channel region and the field plate base point (XGD), for example in a way that places the upper edge of the field plate, i.e. the field plate base point, directly at the vertical position of the lower edge of the p-doped body-/channel region. In this process the semiconductor structure 100 may have a special structure as shown in the cross section in FIG. 1H when the field oxide 930 is formed.

In various embodiments, the applied voltage V_{aO} may be below the mesa depletion voltage (the mesa depletion voltage corresponds to the voltage V_{aO} that is required for depleting the complete mesa, i.e. a voltage V_{aO} that is high enough to cause the borders of adjacent space-charge regions to coincide). This may lead to a situation where the borders of space-charge regions do not yet touch or coincide horizontally in the mesa. In various embodiments, the applied voltage may be higher than the mesa depletion voltage. In that situation, the electric field for the trench side walls 420 may be limited by the width of the mesa, i.e. the thickness of the mesa between its two side walls 420, and by its doping concentration, and it is constant (i.e. independent of Vₐₒ) at an applied voltage Vₐₒ above the mesa depletion voltage. For the trench bottom 422, however, the mesa width may be irrelevant, whereas an increase in Vₐₒ may lead to an increase in the strength of the electric field in the anodically grown oxide near the bottom of the trench 422, and therefore in the thickness of the oxide 930 that can be obtained in that region. This makes it possible to shape the oxide 930 thicker in the region of the trench bottom 422 than near the trench walls 420. For example, the thickness of the oxide 930 in the region of the trench bottom 422 may be in the range from about 20 nm to about 1 μm, for example about 100 nm.

In various embodiments, the doping profile of the mesa may be varied. For example, the doping concentration within the n-doped region 104 may be varied vertically, for example the doping concentration may be varied as a vertical gradient. This may make it possible to influence the thickness of the oxide layer 930 on the trench side wall 420. For example, the vertical gradient of the doping concentration may be used to form an oxide layer with a continuously increasing oxide thickness in the trench side wall.

In various embodiments, anodic alkaline oxidation may not be carried out up to the point of self-limitation (saturation). Instead, the anodic alkaline oxidation may be aborted before self limitation/saturation is reached, which means a time controlled process.

In various embodiments, the applied voltage Vₐₒ may be varied during the anodic alkaline oxidation. For example, the voltage V_{aO} may be lower initially, and may then be increased according to the thickness of the oxide layer already formed. In various embodiments, the voltage Vao may be increased in such a way that the current, and thereby the OH⁻-Diffusion, is kept constant. In various embodiments, the applied voltage V_{aO} may for example be varied between a status where the applied voltage Vₐₒ is kept above the depletion voltage, and a status where the applied voltage Vₐₒ is lowered below the depletion voltage, wherein both these parts of the anodic alkaline oxidation may be performed either with time limitation/control, or with self-limitation/saturation. A large variation of oxide profiles with many degrees of freedom or parameters to be independently determined is possible using an adjustment of parameters influencing the anodic alkaline oxidation, like the applied voltage V_{aO} and its variation with time, the doping profile, mesa width, etc.

As shown in FIG. 1I, the anodic alkaline oxidation leads to the formation of the oxide layer 930. This process may be self-limiting: if the field in the oxide layer 930, which is formed by the oxide layer 624 that was present before the anodic alkaline oxidation and the additional oxide layer formed by the anodic alkaline oxidation, is too small, because the oxide layer 930 is thick enough, the oxide layer 930 cannot be penetrated by further OH⁻-ions. In other words, the diffusion may no longer be possible for the OH⁻-ions, and the oxidation may stop. This means that the thickness of the oxide layer 930 to be reached is determined by the external voltage V_{aO}, wherein V_{aO} may correspond to a maximum voltage, for example to a maximum voltage to be at an end of an oxidation during which the voltage had been increased in order to keep the current constant. Depending on the field strength applied, i.e. on the external voltage Vₒₐ, thicknesses of the oxide layer 930 of more than 1000 nm are possible. In various embodiments, the thickness of the oxide layer 930 may be in the range from about 20 nm to about 500 nm, for example in the range from about 50 nm to about 300 nm.

The oxide layer 930 formed by means of anodic alkaline oxidation may have an advantage of its thickness increasing with increasing distance from the p-doped region 206, which is caused by the field component perpendicular to the trench side wall 420 increasing gradually with increasing distance to the p-doped region 206. This structural feature may be advantageous for the field distribution in the field plate component and may not be accomplished by present manufacturing methods. This structural feature also means that a break-through point is located in the adjacent silicon, not in the oxide.

Another effect of the formation of the oxide layer 930 through anodic alkaline oxidation may be that the formation of the oxide layer 930, the field plate oxide, may not require any temperature process, or only a temperature process with a low temperature budget. In this regard, it may be noted that a production process that uses high temperatures could shift the relative positioning of the lower edge of the body with respect to the upper edge of the field oxide, i.e. the value of XGD. With the p-doped region 206 already formed when the anodic alkaline oxidation is executed, the only remaining process that uses heating is the formation of the gate oxide and the anneling process for the field oxide deposited by means of anodic oxidation. However, low voltage components are usually provided with gate oxides that are thin enough to not shift considerably relative positioning of the lower edge of the body with respect to the upper edge of the field oxide, so that no negative impact is to be expected from the gate formation. However, the upper edge of the oxide layer 930 could be shifted downwards by slight wet chemical etching, if necessary.

Another effect of the formation of the oxide layer 930 by means of anodic alkaline oxidation in combination with an annealing process is that anodic oxides usually have a good electric quality, comparable to thermal oxides. In various embodiments, formation of the oxide layer 930 may be followed by a slight annealing which may further improve the electric quality of the oxide.

In various embodiments, the p⁺⁺-doped region 308 may be removed, as shown in FIG. 1J. In various other embodiments, parts of the p⁺⁺-doped region 308 may remain and may form contact regions for the p-doped body region 206. In various other embodiments, the p⁺⁺-doped region 308 may be re-doped to an n⁺- or n⁺⁺-doped region. An oxide layer 1034 may then be formed on all exposed surfaces, for example via thermal oxidation, for example by exposing the substrate to a temperature of about 1000° C. to form an oxide layer of about 120 nm thickness. Alternatively or additionally, the oxide layer 1034 may be deposited by deposition of, for example, about 100 nm of TEOS, followed by a compaction of the TEOS, for example through heating up to about 1100° C. for about 30 seconds. Then, the trench 418 may be completely filled up with a thick layer of polysilicon 1032, for example by deposition of about 400 nm of polysilicon with a sheet resistance smaller than 30 Ω/sq. In various embodiments, the polysilicon 1032 may then be etched back using a mask 1036, for example by means of a recess etching of the complete surface (except the masked areas), for example by means of isotropic etching, wherein the etching may extend deeply into the trench 418. A wedge of polysilicon 1032 may thus remain in a lower portion of the trench 418, which may form a field plate at source potential.

In various embodiments, a measurement of a depth of a surface of the recessed polysilicon 1032 may be executed. As shown in FIG. 1K, the mask 1036 may then be removed, and a gate mask 1138 may be formed. In a further process, exposed parts of the oxide layer 1034 may be removed, for example by means of full surface isotropic oxide etching, for example by wet chemical etching of the oxide layer 1034. A masked portion of the oxide layer 1034 may thus remain. In other words, the oxide layer 1034 may be removed in all regions except those covered by the polysilicon wedge 1032 in the trench 418 or by the gate mask 1138.

As shown in FIG. 1L, after removal of the gate mask 1138, a gate oxide layer 1240 may be formed. In various embodiments, the oxide 1240 may be formed via thermal oxidation, for example by exposing the substrate to about 860° C. and/or to about 1100° C., in order to form a gate oxide of about 55 nm thickness. In various embodiments, the gate oxide layer 1240 thickness may be in the range from about 20 μm to about 80 μm, for example about 25 μm. Subsequently, a polysilicon gate 1242 may be deposited. In various embodiments, the polysilicon 1242 may be annealed, for example by heating the substrate to about 700° C. for about 30 s. In a further process, the polysilicon 1242 may then be etched (and thereby partially removed), for example by means of isotropic plasma etching, using a further mask 1244. The polysilicon gate 1242 may for example have a thickness of about 600 nm and a sheet resistance smaller than 30 Ω/sq, for example of about 9.5 Ω/sq.

After a depth measurement, in various embodiments, as shown in FIG. 1M, the mask 1244 may then be removed, and a further oxide layer 1346 may be deposited, for example by forming a layer of TEOS, for example with a thickness of about 30 nm. In various embodiments, after formation of a source mask, a source region 1348 and source contacts 1350 may be formed. In various embodiments, the source contacts 1350 may be implanted, for example by implanting arsenic ions with an implant dose of about 3·10¹⁵ cm⁻² at an ion energy of about 120 keV, implanted with a beam incident angle of about 0°. Following another mask removal, the source region 1348 may be formed, for example by implantation of phosphorus ions with an implant dose of about 1·10¹⁴ cm⁻² at an ion energy of about 90 keV, implanted with a beam incident angle of about 0°. In various embodiments, annealing of the implanted phosphorus ions may be performed subsequently, and may include heating, for example heating to about 1100° C. for a duration of about 60 seconds.

In various embodiments, a glass layer 1458 may be deposited, wherein the glass layer 1458 may for example include undoped silicate glass and/or phosphorus silica glass, which may for example have layer thicknesses of about 150 nm and about 400 nm, respectively, and may be compacted, for example by heating, for example by heating up to about 875° C. for about 30 s. In various embodiments, a mask for the formation of trench contact holes may be formed, followed by an etching of the contact holes and a removal of the mask. Following this, trenches 1452 may be etched, for example with a width of about 450 nm and a depth of about 500 nm. Thereafter, an oxide layer, for example a TEOS layer, may be deposited, for example a TEOS layer with a thickness of about 30 nm. In various embodiments, body contacts 1454 may then be implanted, for example by implantation of boron ions with an implant dose of about 3·10¹⁵ cm⁻² at an ion energy of about 25 keV, implanted with a beam incident angle of about 0°, followed by an implantation of boron ions with an implant dose of about 1·10¹⁴ cm⁻² at an ion energy of about 60 keV, implanted with a beam incident angle of about 7°. Following this, metal contacts 1456 may be formed in various embodiments. This may include etching the oxide and sputtering titanium, for example forming a layer of about 45 nm, followed by silicidation, which may for example be performed by heating to about 725° C. for about 30 s and etching of Ti/TiN.

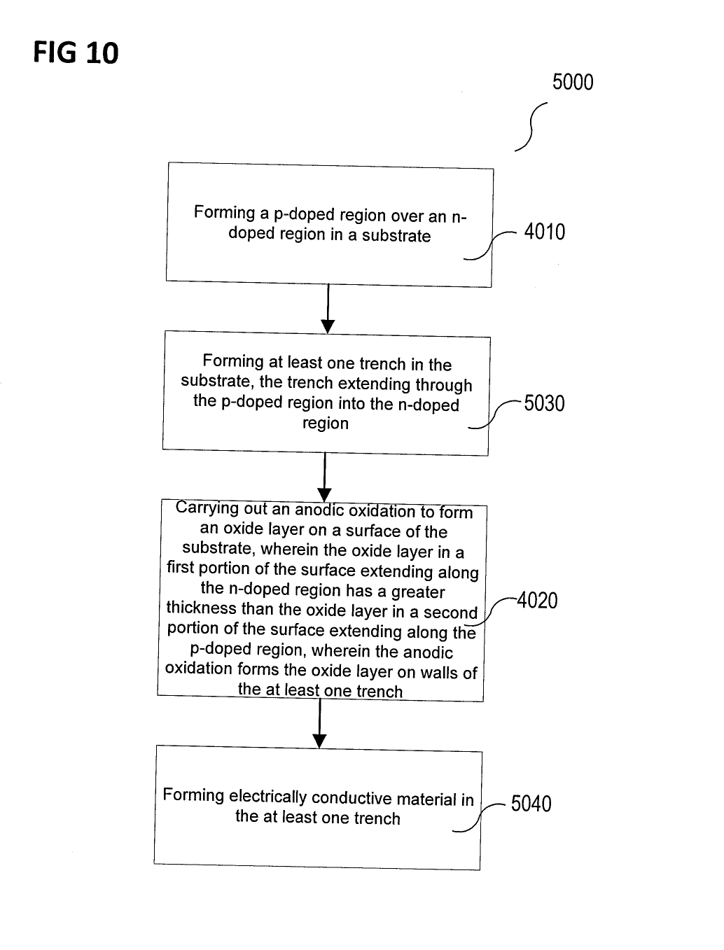

In various embodiments, as shown in FIG. 10, polysilicon may be deposited and etched to form plugs 1560, wherein the polysilicon may for example have a thickness of about 600 nm, and the polysilicon 1742 may be annealed, for example by heating up to about 975° C. for a duration of about 30 s. In various embodiments, after a recess etching of the polysilicon, for example by isotropic plasma etching, a metal layer may be formed, for example via deposition of AlSiCu, for example with a thickness of about 5 μm. The metal layer may be etched, for example via wet chemical etching of the metal using a mask, to form the source contact 1562 and the gate contact 1564. The back side (not shown) may be thinned, for example to about 175 μm.

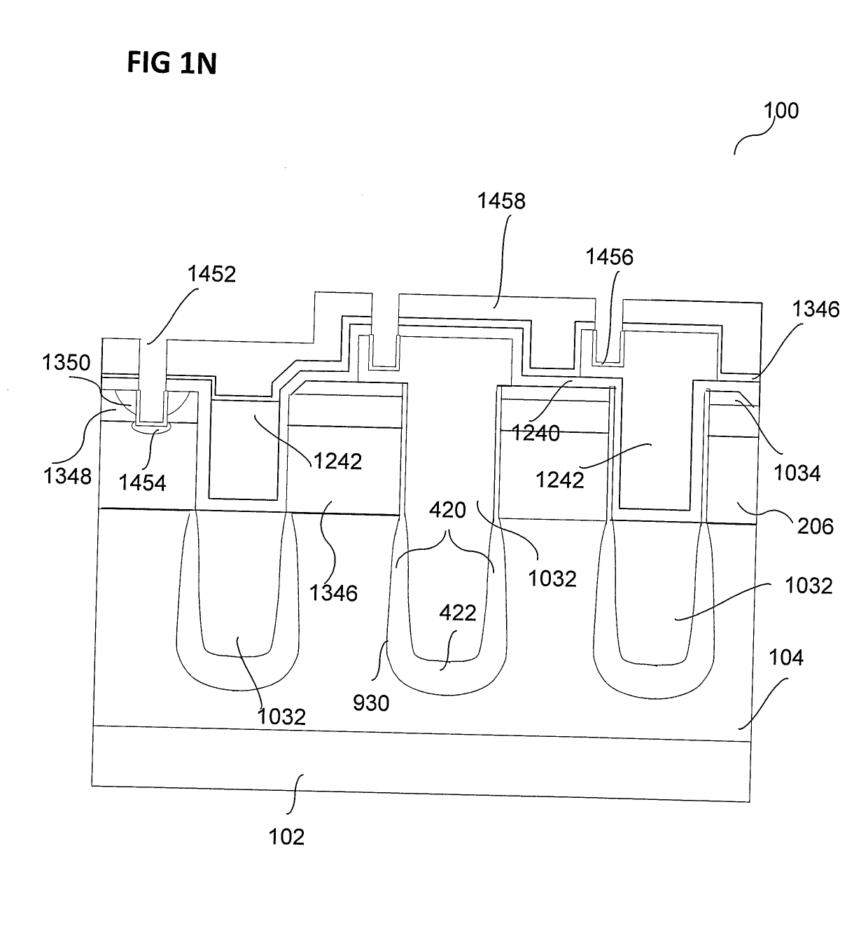

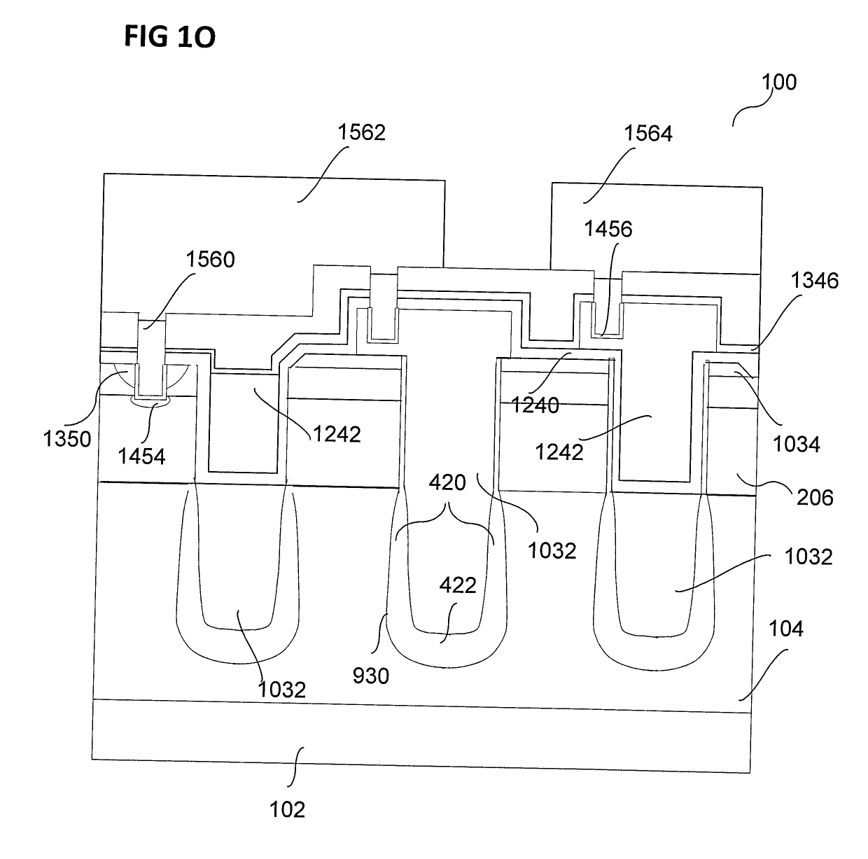

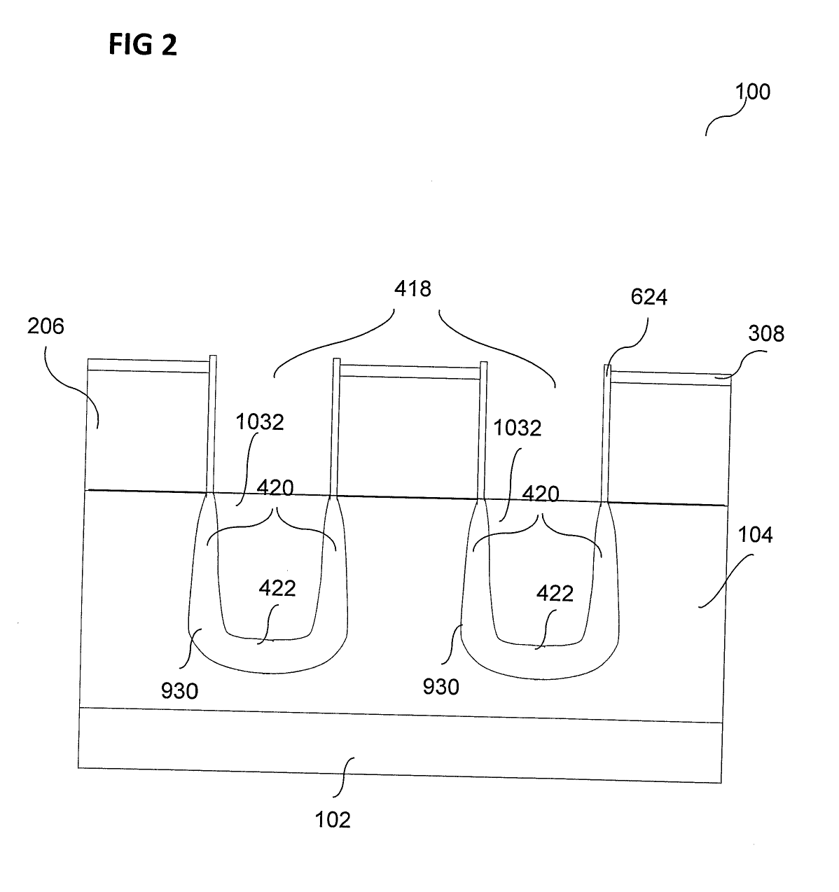

FIG. 2 shows a semiconductor structure 100 in accordance with various embodiments, including a substrate, an n-doped region 104 in the substrate, a p-doped region 206 over the n-doped region 104 in the substrate, at least one trench 418 in the substrate, the trench 418 extending through the p-doped region 206 into the n-doped region 104, an oxide layer 930 covering the sidewalls 420 and the bottom 422 of the at least one trench 418, wherein a first portion of the oxide layer extending into the n-doped region 104 has a greater thickness than the oxide layer in a second portion of the trench extending through the p-doped region 206, wherein the first portion of the oxide layer has a greater lateral extent into the at least one trench 418 as well as into the n-doped region than the second portion of the oxide layer, and electrically conductive material 1032 formed in the at least one trench.

In various embodiments, the semiconductor structure 100 may further include a dielectric layer over the electrically conductive material 1032 within the at least one trench 418, and a further electrically conductive material over the dielectric layer, wherein the further electrically conductive material is electrically isolated from the electrically conductive material by means of the dielectric layer.

In various embodiments, the electrically conductive material may form a field plate within the at least one trench 418.

In various embodiments, the semiconductor structure 100 may further include a thermal oxide layer on the walls 420 of the at least one trench 418.

In various embodiments, the semiconductor structure 100 may further include a second p-doped region over at least a portion of the p-doped region 206.

In various embodiments, the semiconductor structure may include a transistor, wherein the n-doped region may include a first source/drain region of the transistor, wherein the p-doped region may include a body region of the transistor, wherein a further n-doped region may include a second source/drain region of the transistor, and wherein the further electrically conductive material may include a gate region of the transistor.

In various embodiments, the transistor may be a power semiconductor transistor.

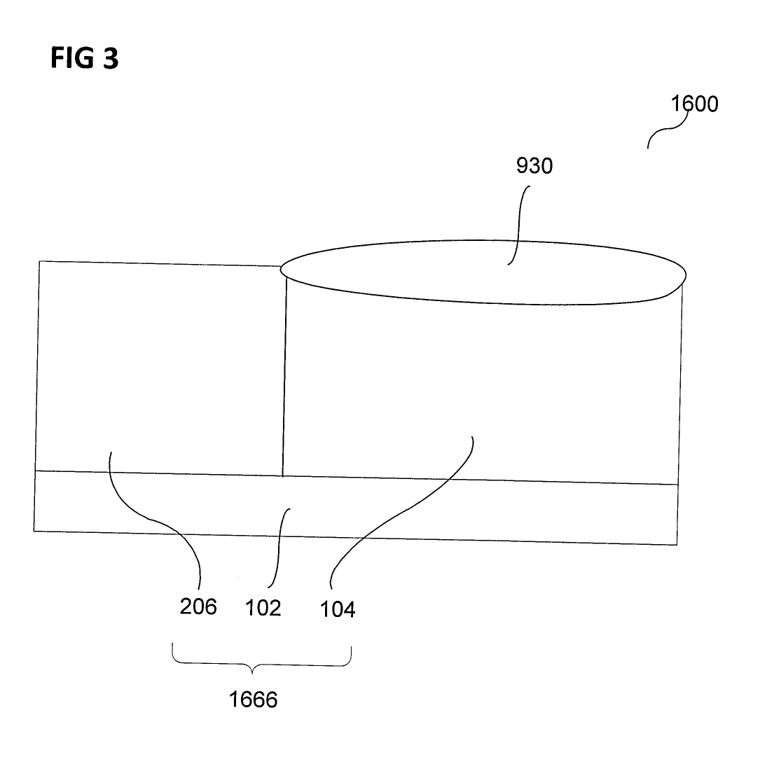

FIG. 3 shows a semiconductor structure 1600 in accordance with various embodiments. FIG. 3 also relates to a method for manufacturing a semiconductor structure 1600 in accordance with various embodiments.

In various embodiments, the method for manufacturing the semiconductor structure 1600 may include forming a p-doped region 206 adjacent to an n-doped region 104 in a substrate 1666; and carrying out an anodic oxidation to form an oxide layer 930 on the substrate 1666, wherein the oxide layer 930 in a first portion of the surface extending along the n-doped region 104 has a greater thickness than the oxide layer 930 in a second portion of the surface extending along the p-doped region 206.

In various embodiments, materials, layer thicknesses, methods of doping, layer deposition, further layers that may be added etc. may correspond to the techniques, materials and parameters described in the context of FIG. 1A to FIG. 10 and FIG. 2.

In various embodiments, carrying out the anodic oxidation according to the method for manufacturing the semiconductor structure 1600 may include inserting the substrate 1666 partially or completely into an alkaline solution.

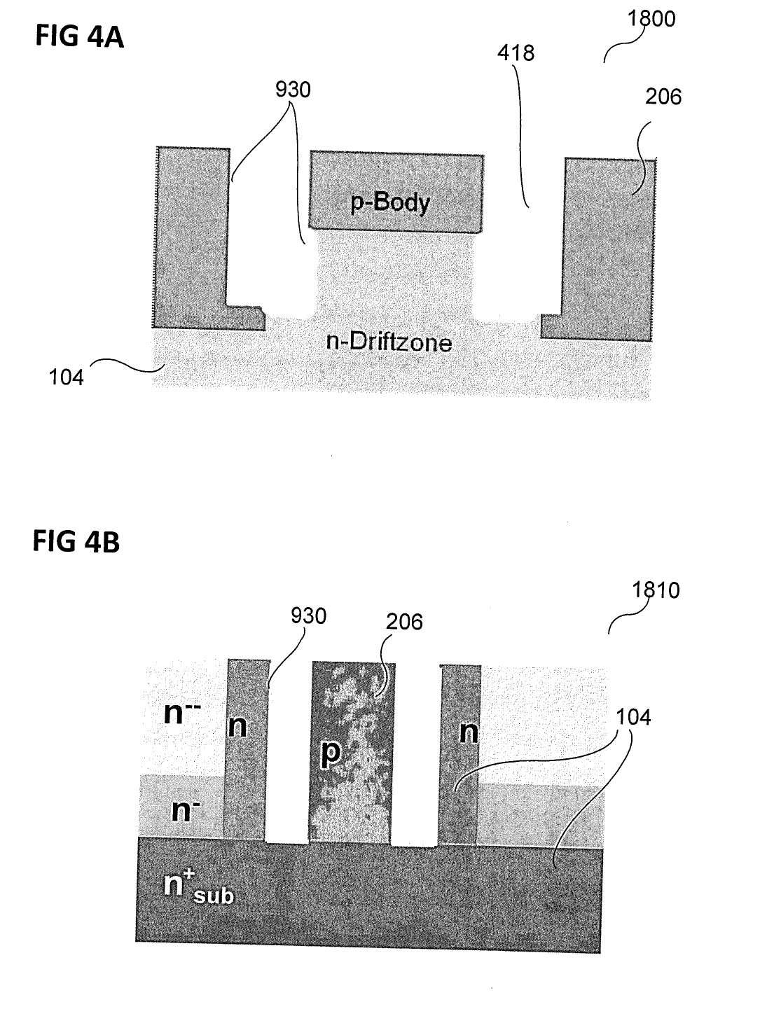

FIG. 4A shows a semiconductor structure 1800 in accordance with various embodiments. FIG. 4A also relates to a method for manufacturing a semiconductor structure 1800 in accordance with various embodiments.

The semiconductor structure 1800 may in many aspects be similar to or the same as the semiconductor structure 100 shown in FIG. 1I as part of the process of manufacturing the semiconductor structure 100 according to various embodiments.

In various embodiments, materials, layer thicknesses, methods of doping, layer deposition, further layers that may be added etc. may correspond to the techniques, materials and parameters described in the context of FIG. 1A to FIG. 10, FIG. 2 and FIG. 3.

In various embodiments, a difference between the semiconductor structure 100 of FIG. 1I and the semiconductor structure 1800 of FIG. 4A may be that in a substrate of the semiconductor structure 1800, which may include a p-doped region 206 and an n-doped region 104, a thickness of the p-doped region 206 may not be the same on both sides (in other words, along two opposite walls) of a trench 418. In other words, doping concentrations (p-doping in region 206 and n-doping in a region 104) in the semiconductor structure 1800 may not be symmetrical with respect to the trench 418. In various embodiments, the p-doped region 206 may extend further into the n-doped region 104 along one wall of the trench 418 than along another wall, for example along the opposite wall, of the trench 418. The p-doped region 206 extending further into the n-doped region 104 may for example extend to a bottom of the trench 418.

In various embodiments, an oxide layer 930 forming by means of anodic oxidation in a first portion of a surface of the substrate extending along the n-doped region 104 may have a greater thickness than the oxide layer 930 in a second portion of the surface extending along the p-doped region 206. In various embodiments, the thickness of the oxide layer 930 may vary unsymetrically with respect to the trench. For example in a case where the p-doped region 206 extends to the bottom of the trench 418, the thicker part of the oxide layer 930 extending along the n-doped region of the substrate may have a cross-section shaped like a letter “L” (unlike a case with a symmetrical arrangement of the n-doped region 104 and the p-doped region 206 with respect to the trench 418, where the thicker part of the oxide layer 930 extending along the n-doped region 104 of the substrate may have a cross-section shaped like a letter “U”).

In various embodiments, seen from above, the trench may for example be shaped like a strip or like a rectangle.

FIG. 4B shows a semiconductor structure 1810 in accordance with various embodiments. FIG. 4B also relates to a method for manufacturing a semiconductor structure 1810 in accordance with various embodiments.

The semiconductor structure 1810 may in many aspects be similar to or the same as the semiconductor structure 1800 shown in FIG. 4A.

In various embodiments, materials, layer thicknesses, methods of doping, layer deposition, further layers that may be added etc. may correspond to the techniques, materials and parameters described in the context of FIG. 1A to FIG. 10, FIG. 2, FIG. 3 and FIG. 4A.

In various embodiments, similar to the semiconductor structure 1800 of FIG. 4A, a p-dopend region 206 and an n-doped region 104 of a substrate of the semiconductor structure 1810 may not be arranged symmetrically with respect to a trench 418. In various embodiments, the n-doped region 104 may extend along one wall of the trench 418, and the p-doped region 206 may extend along an opposite wall of the trench 418. The n-doped region may also extend along the bottom of the trench. The n-doped region 104 may also be n+-doped, for example along the bottom of the trench 418.

In various embodiments, the semiconductor structure 1810 may include two adjacent trenches 418. The walls of the two adjacent trenches 418 facing away from the respective other trench 418 and the part 104 of the substrate underneath the bottom of the trenches may be n-doped, and the walls of the trenches 418 between the two trenches may be p-doped. Another way to describe the structure of these various embodiments would be a broad trench with n-doped side- and bottom walls and a mesa-like p-doped structure located in the middle of the trench and connected to the bottom wall of the trench, thereby forming two trenches 418. Various embodiments of such a semiconductor structure 1810 may for example be used in a superjunction device. On a side of the semiconductor structure 1810 opposite the trench 418, planar metal oxide semiconductor (MOS) cells may for example be arranged (not shown).

In various embodiments, an anodic oxidation of the semiconductor structure 1810 may form an oxide layer 930 that is thicker in a first portion of a surface of the substrate extending along the n-doped region 104 than in a second portion of the surface extending along the p-doped region 206. In various embodiments, the thinner part of the oxide layer 930 extending along the p-doped region 206 may be removed, for example by means of etching. The etching may also remove part of the oxide layer 930 formed over the n-doped region 104, but a part of the oxide layer 930 may remain along the n-doped region, because it had formed there with a greater thickness.

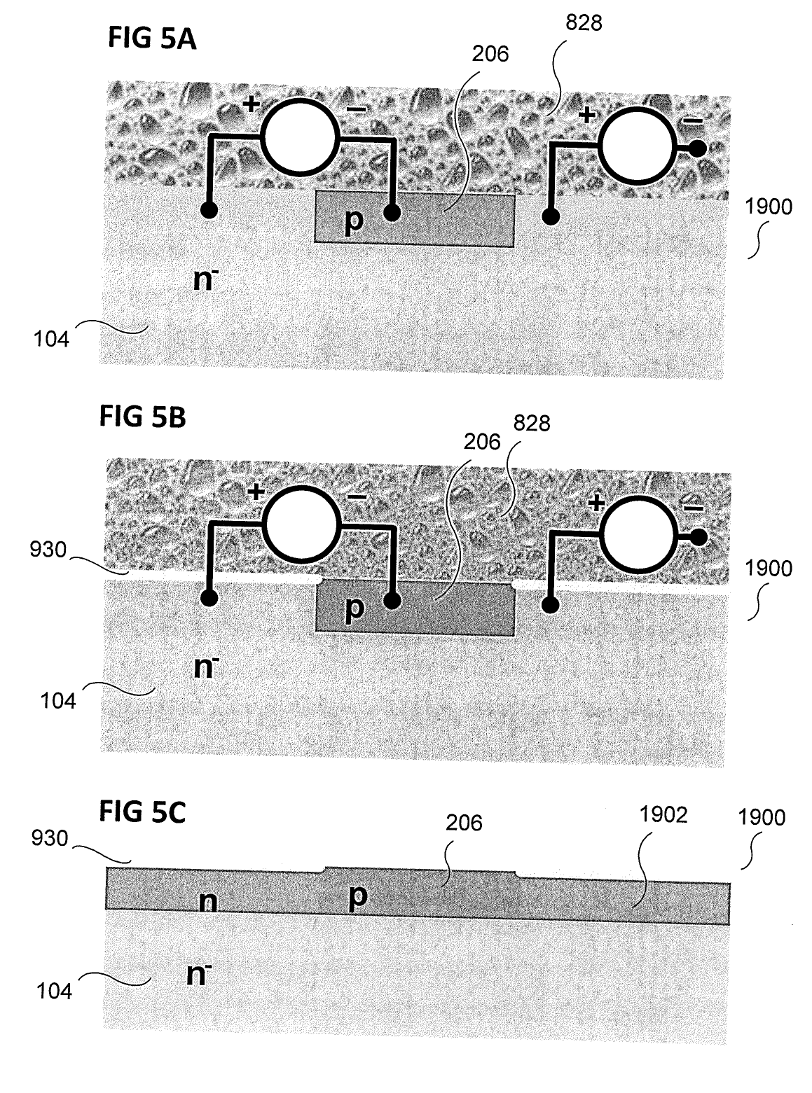

FIG. 5A to FIG. 5C show three stages of a process flow for a method for manufacturing a semiconductor structure 1900 in accordance with various embodiments.

A setup for an anodic oxidation as shown in FIG. 5A and FIG. 5B may be similar to an anodic oxidation as shown in FIG. 1H and FIG. 1I. In various embodiments, materials, parameters, processes etc. described in context with FIG. 1A to FIG. 1O, FIG. 2, FIG. 3, FIG. 4A and FIG. 4B may be the same or similar to those used for the method for manufacturing the semiconductor structure 1900.

A difference between the semiconductor structure 100 being subjected to anodic oxidation in FIG. 1H and the semiconductor structure 1900 of FIG. 5A to 5C may be that the semiconductor structure 1900 is not shaped as a trench, but planar. Consequently, a p-doped region 206 and an n-doped region 104 may be arranged next to each other or adjacent to each other more or less within the same plane of a surface of a substrate of the semiconductor structure 1900, wherein the substrate includes at least the n-doped region 104 and the p-doped region 206.

In various embodiments, a low level n⁻-doping of the n-doped region 104 may allow for a high voltage across a p-n-junction between the p-doped region 206 and the n-doped region 104. An oxide layer 930 may form on the surface of the substrate, wherein the oxide layer 930 in a first portion of the surface extending along the n-doped region 104 may have a greater thickness than the oxide layer 930 in a second portion of the surface extending along the p-doped region 206. The greater thickness of the oxide layer 930 along the n-doped region 104 may lead to a higher field strength towards an electrolyte 828 used for performing the anodic oxidation, and thereby to the formation of an even thicker oxide layer 930. In various embodiments, the oxide layer 930 forming along the p-doped region 206 may be thin or negligible. It may be removed by means of a short, isotrope etching.

As shown in FIG. 5C, after forming the oxide layer 930 by means of anodic oxidation (and optionally removing the thin oxide layer 930 that may have formed along the p-doped region), in various embodiments, doping of the semiconductor structure 1900 may be performed, for example by means of ion implantation. Doping may be performed in a region 1902 located in the n-doped region 104 underneath the oxide layer 930. For example, the low-level n⁻-doping may be changed to a higher level n-doping in the region 1902. In various embodiments, other regions of the semiconductor structure 1900 may undergo doping after the forming of the oxide layer 930.

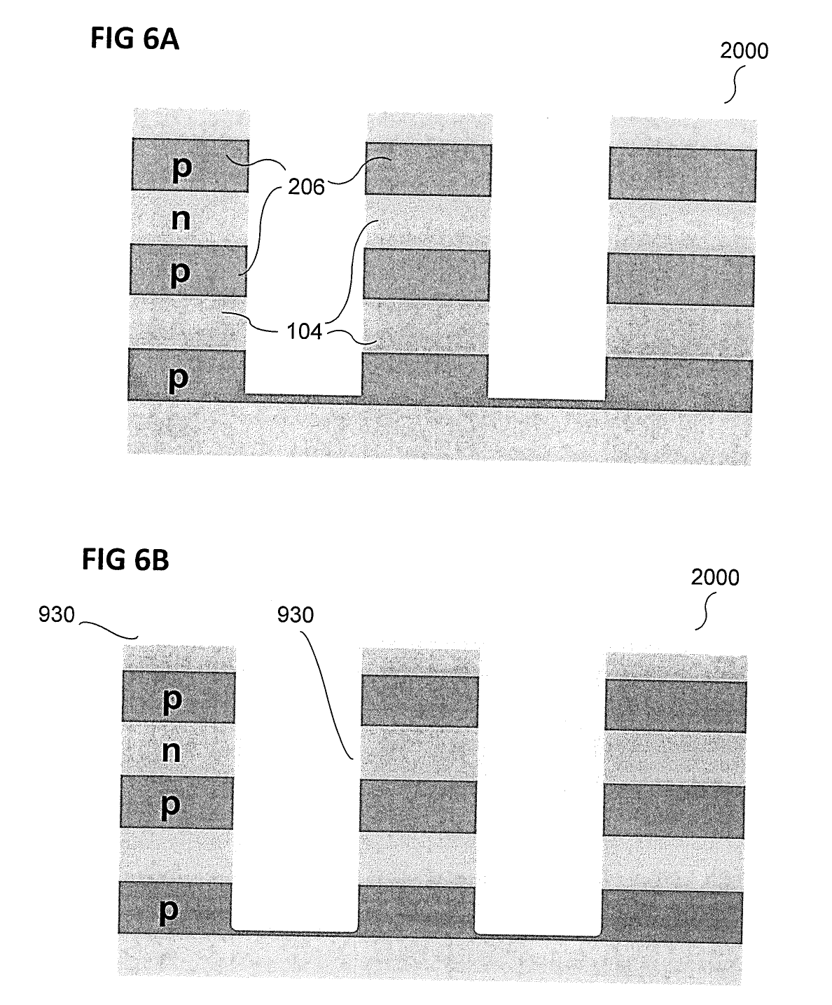

FIG. 6A and FIG. 6B show two stages of a process flow for a method for manufacturing a semiconductor structure 2000 in accordance with various embodiments.

The semiconductor structure 2000 may in many aspects be similar to or the same as the semiconductor structure 100 shown in FIG. 1I and/or to the semiconductor structures 1800 and 1810 shown in FIG. 4A and FIG. 4B, respectively.

In various embodiments, materials, layer thicknesses, methods of doping, layer deposition, further layers that may be added etc. may correspond to the techniques, materials and parameters described in the context of FIG. 1A to FIG. 10, FIG. 2, FIG. 3, FIG. 4A, FIG. 4B and/or FIG. 5A to FIG. 5C.

In various embodiments, a difference between the semiconductor structure 2000 shown in FIG. 6A and in FIG. 6B and the semiconductor structures 100, 1800 and 1810 shown in FIG. I1, FIG. 4A and FIG. 4B, respectively, may be that a trench 418 in the semiconductor structure 2000 may expose several, for example alternating, p- and n-doped regions 206 and 104, respectively. The p-doped regions 206 and the n-doped regions 104 may for example alternate along walls of the trench 418, and may not alternate along a bottom of the trench 418. In other words, the p-doped regions 206 and the n-doped regions 104 may be layered alternatingly in a vertical direction, and the trench 418 may be formed through and/or into the alternating layers 104, 206. In various other embodiments, the p-doped layer 206 and the n-doped layer may be layered alternatingly in a horizontal direction.

An oxide layer 930 may be formed on surfaces of the trench 418 analogously to the anodic oxidation described in context with FIG. 1H, wherein the oxide layer 930 in a first portion of the surface extending along the n-doped regions 104 may have a greater thickness than the oxide layer 930 in a second portion of the surface extending along the p-doped regions 206. In various embodiments, the oxide layer 930 forming along the p-doped regions 206 may be thin or negligible. It may be removed by means of a short, isotrope etching. Thereby, a vertically structured oxide layer 930 may be formed. In various embodiments, the oxide layer 930 may have holes or openings, in particular within the trench 418.

In various embodiments, the forming of the oxide layer 930 may be followed by a diffusion of the doping regions 104, 206. If the p-doped region 206 and the n-doped region 104 had been doped at the same level, this may lead to an essentially undoped region, e.g. an undoped semiconductor. In various other embodiments, if the p-doped region 206 and the n-doped region 104 had been doped at different levels, this may lead to a region with a net-doping, i.e. a doping level that remains after the n-doping and the p-doping that correspond to each other cancel out, that is either an n-doping or a p-doping, at a lower level than the respective doping of the region 104 or 206, respectively.

In various embodiments, the trench 418 may be filled by semiconductor material. If, for example, the p-doped regions (layers) 206 had been thin as compared with the n-doped regions (layers) 104, the semiconductor filling may be coupled to a potential, whereas an inter-diffusion of dopants during the manufacturing or an inter-diffusion of mobile carriers (for example, an electron-hole-plasma) during operation may be significantly reduced.

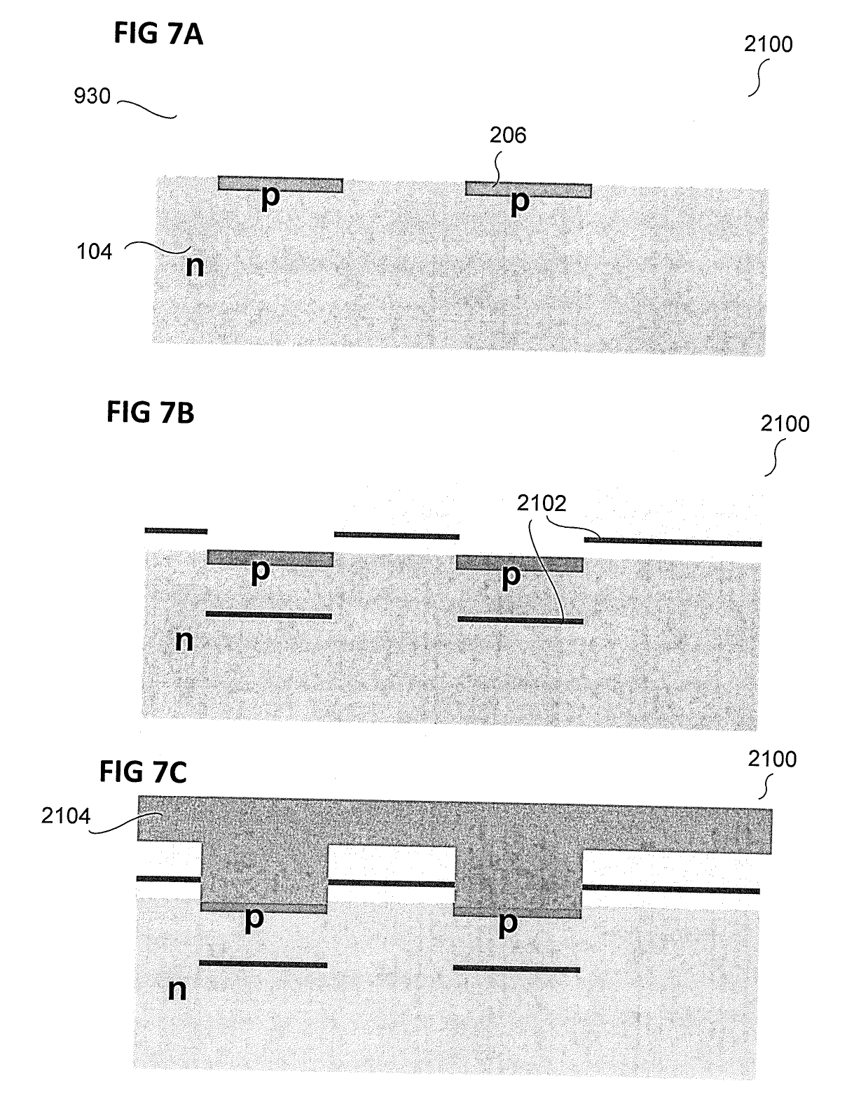

FIG. 7A to FIG. 7C show three stages of a process flow for a method for manufacturing a semiconductor structure 2100 in accordance with various embodiments.

The semiconductor structure 2100 may in many aspects be similar to or the same as the semiconductor structure 1900 shown in FIG. 5A to FIG. 5C and the further semiconductor structures referred to in context with FIG. 5A to FIG. 5C.

In various embodiments, materials, layer thicknesses, methods of doping, layer deposition, further layers that may be added, etc., may correspond to the techniques, materials and parameters described in the context of any of the previously described methods and semiconductor structures.

In various embodiments, as shown in FIG. 7A, the semiconductor structure 2100 may include an n-doped region 104 and p-doped regions 206, which may be arranged alternatingly along a surface of a substrate of the semiconductor structure 2100. The surface may for example form a plane. An oxide layer 930 may have been formed by means of anodic oxidation on the surface, wherein the oxide layer 930 may have a greater thickness along the n-doped region 104 than along the p-doped regions 206. The oxide layer 930 that may have formed along the p-doped regions 206 may have been removed, for example by means of etching.

As shown in FIG. 7B, in various embodiments, a further doping may be executed, for example an n-doping. The oxide layer 930 may serve as a mask for the n-doping. In various embodiments, doping parameters may be selected in such a way that a doped layer 2102 may form in a certain depth with respect to a new horizontal surface of the semiconductor structure 2100, wherein the new horizontal surface is formed by the surface of the p-doped regions 206 and a horizontal part (i.e., a part parallel to the surface of the p-doped regions 206) of a surface of the oxide layer 930. Said certain depth may be located such that the doped layer 2102 is within the oxide layer 930, and only in areas underneath the p-doped regions 206, where the n-doped region 104 is unmasked by the oxide layer 930, may the doped layer 2102 reach a depth where it is located within the n-doped region 104 (or, more generally, within the semiconductor). In this way, in various embodiments, a stepped field stop may be formed. Doping may, in various embodiments, be executed by means of implantation. In various embodiments, microwave-supported annealing may be used, such that only temperatures need to be applied that may be compatible with structures already formed on/in the semiconductor structure 2100, for example metallizations.

In various embodiments, the doping after forming of the oxide layer 930 may be performed in such a way (for example with high energy) that the doped layer 2102 is located within the n-doped region 104 also underneath the oxide layer 930.

In various embodiments, the doping after forming of the oxide layer 930 may be performed with low energy.

As shown in FIG. 7C, implantation (and optionally annealing) may be followed by an etching of the oxide layer 930, and optionally of the p-doped region 206. In various embodiments, a metallization layer may be formed over the oxide layer 930 and/or over the p-doped regions 206.

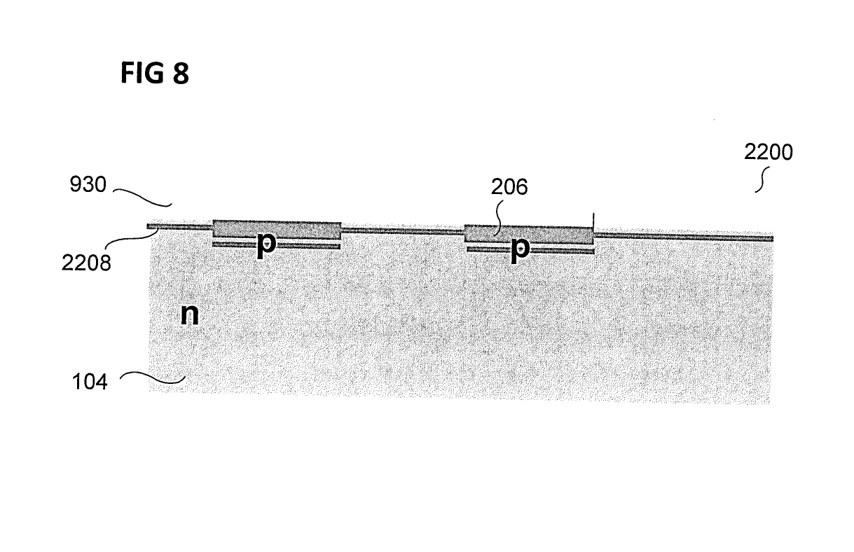

FIG. 8 shows a semiconductor structure 2200 in accordance with various embodiments. The semiconductor structure 2200 may in many aspects be similar or identical to the semiconductor structure 2100 of FIG. 7B, and many of its structures may have been formed using the same method, materials etc. as described in context with FIG. 7A to FIG. 7C. Some of the differences that may occur during a manufacture of the semiconductor structure 220 will be specified here.

As shown in FIG. 8, in various embodiments, the doped layer (comparable to the doped layer 2102 shown in FIG. 7B and FIG. 7C) may be a p-doped layer 2208. The p-doped layer 2208 may for example form p-back side emitters of an insulated gate bipolar transistor. In various embodiments, a p-doping may be performed at a high energy and with a small doseage, such that the p-doped layer 2208 forms inside the n-doped region 104 also underneath the masking oxide layer 930. In various other embodiments, a low energy may be used for the forming of the p-doped layer 2208 and/or for additional doping of the p-doped region 206.

FIG. 9 shows a schematic diagram 4000 of a method of manufacturing a semiconductor structure 100 according to various embodiments.

The method for manufacturing the semiconductor structure 100 may include: forming a p-doped region adjacent to an n-doped region in a substrate (in 4010); carrying out an anodic oxidation to form an oxide layer on a surface of the substrate, wherein the oxide layer in a first portion of the surface extending along the n-doped region has a greater thickness than the oxide layer in a second portion of the surface extending along the p-doped region (in 4020).

As shown in FIG. 10, in various embodiments the method for forming the semiconductor structure may further include forming at least one trench in the substrate, the trench extending through the p-doped region into the n-doped region (in 5030); and forming electrically conductive material in the at least one trench (in 5040), and in 4020, the anodic oxidation may form the oxide layer on walls of the at least one trench.

In various embodiments, the method of manufacturing a semiconductor structure 100 may further include forming a dielectric layer over the electrically conductive material within the at least one trench; and of forming further electrically conductive material over the dielectric layer, wherein the further electrically conductive material is electrically isolated from the electrically conductive material by means of the dielectric layer.

In various embodiments, the electrically conductive material may form a field plate within the at least one trench.

In various embodiments, the method of manufacturing a semiconductor structure 100 may further include carrying out a thermal oxidation to form a thermal oxide layer on the walls of the at least one trench before carrying out the anodic oxidation. In various embodiments, this may be carried out according to the embodiments and examples for carrying out a thermal oxidation described in the context of FIG. 1G and/or of FIG. 3.

In various embodiments, the forming the p-doped region may include implanting p-doping atoms into the substrate and carrying out a diffusion process to diffuse the implanted p-doping atoms. In various embodiments, the forming the p-doped region may include epitaxially growing the p-doped region on the n-doped region. In various embodiments, the implanting or the epitaxial growing may be carried out according to the embodiments and examples for forming the p-doped region described in the context of FIG. 1B and/or of FIG. 3.

In various embodiments, the carrying out the anodic oxidation may include filling the at least one trench with an alkaline liquid, and applying an electric voltage between the alkaline liquid and the substrate. In various embodiments, the carrying out the anodic oxidation may be performed according to the embodiments and examples described in the context of FIG. 1G, FIG. 1H and/or FIG. 3.

In various embodiments, the method of manufacturing a semiconductor structure 100 may further include forming a further p-doped region having a larger p-conductivity than the p-doped region over at least a portion of the p-doped region, wherein said further p-doped region may correspond to the p⁺⁺-doped region 308, and the forming the further p-doped/p⁺⁺-region may be executed according to the embodiments and examples described in the context of FIG. 1C.

In various embodiments, at least a portion of the further region or the p⁺⁺-doped region, respectively, or of the p-doped region, may be exposed during the anodic oxidation to form an electric contact for the anodic oxidation.

In various embodiments of the method of manufacturing a semiconductor structure 100, the semiconductor structure may include a transistor, the n-doped region may include a first source/drain region of the transistor, the p-doped region may include a body region of the transistor, a further n-doped region may include a second source/drain region of the transistor, and the further electrically conductive material may include a gate region of the transistor.

In various embodiments of the method of manufacturing a semiconductor structure 100, the transistor may be a power semiconductor transistor.

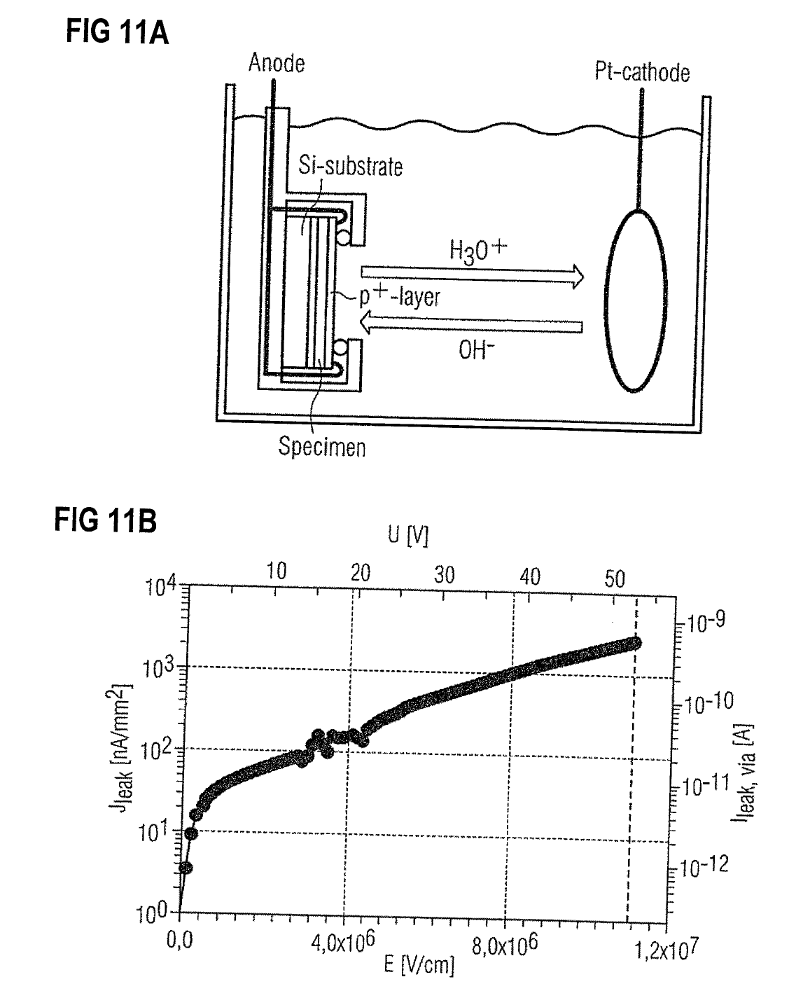

FIG. 11A shows a schematic for a principle setup for anodic alkaline oxidation. By using the method of anodic alkaline oxidation, it is possible to selectively oxidize only some of differently doped semiconductor areas.

Basic solutions, for example alkaline solutions (e.g. KOH, TMAH or KNO₃), or more generally any alkaline solutions supplying OH⁻ ions, usually dissociate into positively and negatively charged molecular parts. KNO₃ for example reacts according to the following reaction equation:

KNO₃+H₂O→K⁺+OH⁻+HNO₃ (1)

If suitable conditions are fulfilled, OH⁻-ions from the alkaline that come into contact with silicon of the specimen can be used for forming an oxide layer. It is, however, provided that the supply of OH⁻ to the silicon is maintained via diffusion through the oxide layer that is already formed. The method of anodic oxidation uses an electric field to cause said diffusion. FIG. 11A shows a corresponding known experimental setup.

FIG. 11B shows a graph of a measurement of a leakage current of one via interconnect with approximately 50 nm anodic oxide deposition after 200 nm PECVD oxide deposition.

FIG. 12 shows a graph of an etching rate as a function of boron doping for different concentrations of KOH. The etching rate drops for very high/degenerate doping concentrations.

FIG. 13 shows a graph of a field strength component vertical to a trench wall as a function of a vertical coordinate z, wherein the vertical coordinate z is running from point A to point B in the cut indicated by the dash-dotted line in FIG. 1H. Compare also the structure of the space-charge region, the borders of which are indicated by dashed lines 826 in FIG. 1H.

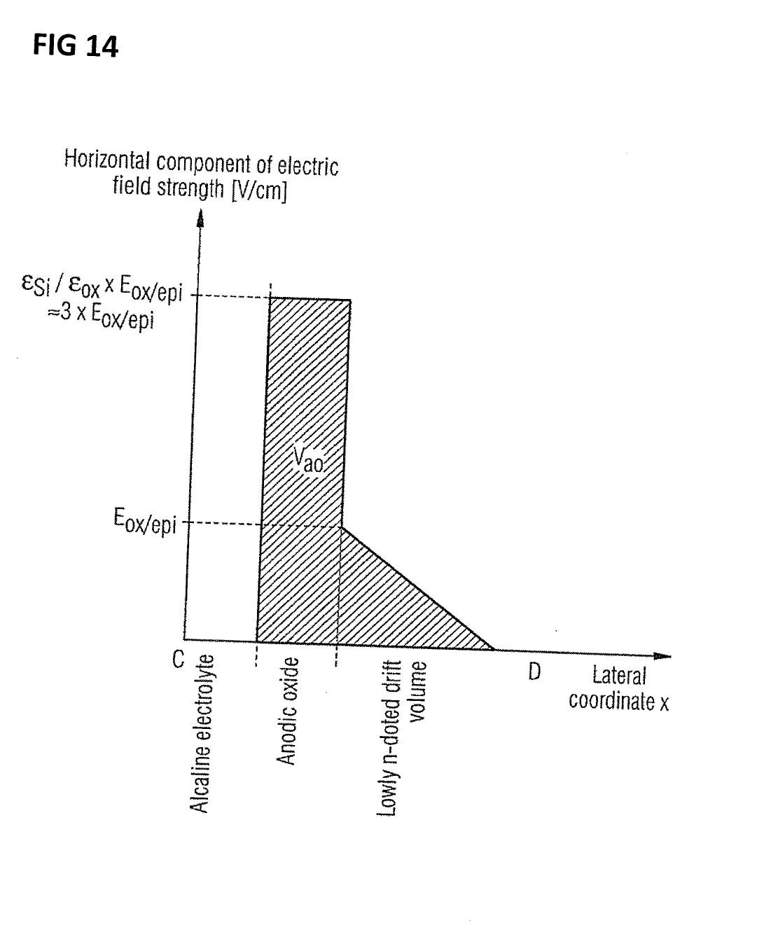

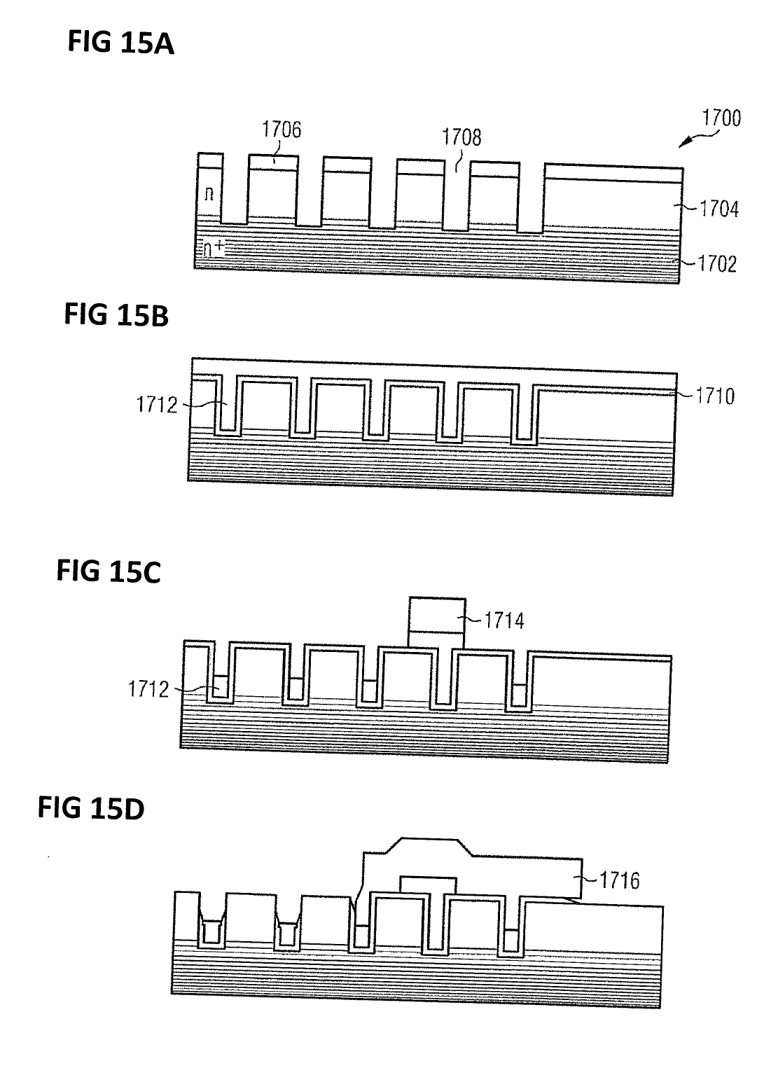

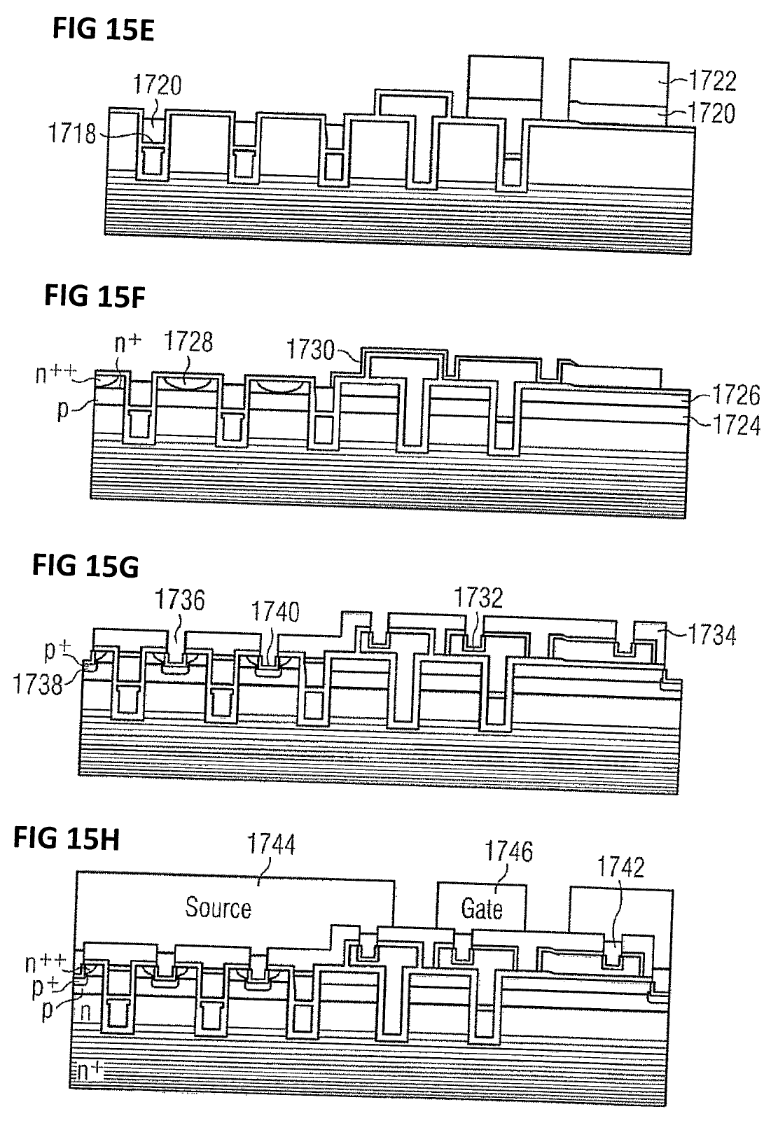

FIG. 14 shows a graph of a horizontal component of an electrical field strength as a function of a lateral coordinate x, wherein the lateral coordinate x extends from point C to point D in the cut indicated by the dash-dotted line in FIG. 1H.

In various embodiments, a method of manufacturing a semiconductor structure is provided. The method may include: forming a p-doped region over an n-doped region in a substrate; carrying out an anodic oxidation to form an oxide layer on a surface of the substrate, wherein the oxide layer in a first portion of the surface extending along the n-doped region has a greater thickness than the oxide layer in a second portion of the surface extending along the p-doped region; and forming electrically conductive material in the at least one trench.

The method may further include: forming at least one trench in the substrate, the trench extending through the p doped region into the n-doped region; forming electrically conductive material in the at least one trench, wherein the anodic oxidation forms the oxide layer on walls of the at least one trench; forming a dielectric layer over the electrically conductive material within the at least one trench; and forming further electrically conductive material over the dielectric layer, wherein the further electrically conductive material is electrically isolated from the electrically conductive material by means of the dielectric layer. Furthermore, the electrically conductive material may form a field plate within the at least one trench. In various embodiments, the method may further include carrying out a thermal oxidation to form a thermal oxide layer on the walls of the at least one trench before carrying out the anodic oxidation. Forming the p-doped region may include: implanting p-doping atoms into the substrate; and carrying out a diffusion process to diffuse the implanted p-doping atoms. Moreover, forming the p-doped region may include epitaxially growing the p-doped region on the n-doped region. Carrying out the anodic oxidation may include: filling the at least one trench with an alkaline liquid; applying an electric voltage between the alkaline liquid and the substrate. In various embodiments, the method may further include forming a further p-doped region having a larger p-conductivity than the p-doped region over at least a portion of the p-doped region. During the anodic oxidation, at least a portion of the further region may be exposed to form an electric contact for the anodic oxidation. Furthermore, during the anodic oxidation, at least a portion of the p-doped region may be exposed to form an electric contact for the anodic oxidation. In various embodiments, the semiconductor structure may include a transistor; wherein the n-doped region comprises a first source/drain region of the transistor; wherein the p-doped region comprises a body region of the transistor; wherein a further n-doped region comprises a second source/drain region of the transistor, and wherein the further electrically conductive material comprises a gate region of the transistor. The transistor may be a power semiconductor transistor.

In various embodiments, a semiconductor structure is provided. The semiconductor structure may include: a substrate; an n-doped region in the substrate; a p-doped region adjacent to the n-doped region in the substrate; an oxide layer covering a surface of the substrate, wherein a first portion of the oxide layer extending along the n-doped region has a greater thickness than the oxide layer in a second portion extending along the p-doped region, wherein the first portion of the oxide layer has a greater extent in a direction away from the substrate as well as into the n-doped region than the second portion of the oxide layer.

The semiconductor structure may further include: at least one trench in the substrate, the trench extending through the p doped region into the n-doped region; and electrically conductive material formed in the at least one trench, wherein the oxide layer covers the sidewalls and the bottom of the at least one trench, and wherein the direction of the extent of the oxide away from the substrate is the direction into the at least one trench.

Moreover, the semiconductor structure may include a dielectric layer over the electrically conductive material within the at least one trench; and a further electrically conductive material over the dielectric layer; wherein the further electrically conductive material is electrically isolated from the electrically conductive material by means of the dielectric layer. In various embodiments, the electrically conductive material may form a field plate within the at least one trench. Moreover, the semiconductor structure may further include a thermal oxide layer on the walls of the at least one trench. The semiconductor structure may further include a second p-doped region over at least a portion of the p-doped region. Furthermore, the semiconductor structure may further include a transistor; wherein the n-doped region may include a first source/drain region of the transistor; wherein the p-doped region may include a body region of the transistor; wherein a further n-doped region may include a second source/drain region of the transistor, and wherein the further electrically conductive material may include a gate region of the transistor. In various embodiments, the transistor may be a power semiconductor transistor.

In various embodiments, a method of manufacturing a semiconductor structure is provided. The method may include: forming a p-doped region over an n-doped region in a substrate; forming at least one trench in the substrate, the trench extending through the p-doped region into the n-doped region; carrying out an anodic oxidation to form an oxide layer on the walls of the at least one trench; and forming electrically conductive material in the at least one trench.

In various embodiments, the method may further include forming a dielectric layer over the electrically conductive material within the at least one trench; and forming further electrically conductive material over the dielectric layer, wherein the further electrically conductive material is electrically isolated from the electrically conductive material by means of the dielectric layer. Forming the p-doped region may include epitaxially growing the p-doped region on the n-doped region. Furthermore, carrying out the anodic oxidation may include: filling the at least one trench with an alkaline liquid; and applying an electric voltage between the alkaline liquid and the substrate. In various embodiments, the method may further include forming a further p-doped region having a larger p-conductivity than the p-doped region over at least a portion of the p-doped region. In various embodiments, during the anodic oxidation, at least a portion of the further p-doped region may be exposed to form an electric contact for the anodic oxidation. Furthermore, during the anodic oxidation, at least a portion of the p-doped region may optionally be exposed to form an electric contact for the anodic oxidation. In various embodiments, the semiconductor structure may include a power semiconductor structure.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of manufacturing a semiconductor structure, the method comprising:
forming a p-doped region adjacent to an n-doped region in a substrate; and
carrying out an anodic oxidation to form an oxide layer on a surface of the substrate, wherein the oxide layer in a first portion of the surface extending along the n-doped region has a greater thickness than the oxide layer in a second portion of the surface extending along the p-doped region.

2. The method of claim 1, further comprising:
forming at least one trench in the substrate, the trench extending through the p-doped region into the n-doped region; and
forming electrically conductive material in the at least one trench,
wherein the anodic oxidation forms the oxide layer on walls of the at least one trench.

3. The method of claim 2, further comprising:
forming a dielectric layer over the electrically conductive material within the at least one trench; and
forming further electrically conductive material over the dielectric layer, wherein the further electrically conductive material is electrically isolated from the electrically conductive material by means of the dielectric layer.

4. The method of claim 3,
wherein the electrically conductive material forms a field plate within the at least one trench.

5. The method of claim 2, further comprising:
carrying out a thermal oxidation to form a thermal oxide layer on the walls of the at least one trench before carrying out the anodic oxidation.

6. The method of claim 2,
wherein forming the p-doped region comprises:
implanting p-doping atoms into the substrate; and
carrying out a diffusion process to diffuse the implanted p-doping atoms.

7. The method of claim 1,
wherein forming the p-doped region comprises:
epitaxially growing the p-doped region on the n-doped region.

8. The method of claim 2,
wherein carrying out the anodic oxidation comprises:
filling the at least one trench with an alkaline liquid;
applying an electric voltage between the alkaline liquid and the substrate.

9. The method of claim 1, further comprising:
forming a further p-doped region having a larger p-conductivity than the p-doped region over at least a portion of the p-doped region.

10. The method of claim 9,
wherein during the anodic oxidation, at least a portion of the further region is exposed to form an electric contact for the anodic oxidation.

11. The method of claim 1,
wherein during the anodic oxidation, at least a portion of the p-doped region is exposed to form an electric contact for the anodic oxidation.

12. The method of claim 1,
wherein the semiconductor structure comprises a transistor;
wherein the n-doped region comprises a first source/drain region of the transistor;
wherein the p-doped region comprises a body region of the transistor;
wherein a further n-doped region comprises a second source/drain region of the transistor, and
wherein the further electrically conductive material comprises a gate region of the transistor.

13. A semiconductor structure, comprising:
a substrate;
an n-doped region in the substrate;
a p-doped region adjacent to the n-doped region in the substrate;
an oxide layer covering a surface of the substrate, wherein a first portion of the oxide layer extending along the n-doped region has a greater thickness than the oxide layer in a second portion extending along the p-doped region, wherein the first portion of the oxide layer has a greater extent in a direction away from the substrate as well as into the n-doped region than the second portion of the oxide layer.

14. The semiconductor structure of claim 13, further comprising:
at least one trench in the substrate, the trench extending through the p-doped region into the n-doped region; and
electrically conductive material formed in the at least one trench,
wherein the oxide layer covers the sidewalls and the bottom of the at least one trench, and
wherein the direction of the extent of the oxide away from the substrate is the direction into the at least one trench.

15. The semiconductor structure of claim 14, further comprising:
a dielectric layer over the electrically conductive material within the at least one trench; and
a further electrically conductive material over the dielectric layer;
wherein the further electrically conductive material is electrically isolated from the electrically conductive material by means of the dielectric layer.

16. The semiconductor structure of claim 14,
wherein the electrically conductive material forms a field plate within the at least one trench.

17. The semiconductor structure of claim 14, further comprising:
a thermal oxide layer on the walls of the at least one trench.

18. The semiconductor structure of claim 13, further comprising:
a second p-doped region over at least a portion of the p-doped region.

19. The semiconductor structure of claim 13,
wherein the semiconductor structure comprises a transistor;
wherein the n-doped region comprises a first source/drain region of the transistor;
wherein the p-doped region comprises a body region of the transistor;
wherein a further n-doped region comprises a second source/drain region of the transistor, and
wherein the further electrically conductive material comprises a gate region of the transistor.

20. A method of manufacturing a semiconductor structure, the method comprising:
forming a p-doped region over an n-doped region in a substrate;
forming at least one trench in the substrate, the trench extending through the p-doped region into the n-doped region;
carrying out an anodic oxidation to form an oxide layer on the walls of the at least one trench; and
forming electrically conductive material in the at least one trench.

21. The method of claim 20, further comprising:
forming a dielectric layer over the electrically conductive material within the at least one trench; and
forming further electrically conductive material over the dielectric layer,
wherein the further electrically conductive material is electrically isolated from the electrically conductive material by means of the dielectric layer.

22. The method of claim 20,
wherein forming the p-doped region comprises:
epitaxially growing the p-doped region on the n-doped region.

23. The method of claim 20,
wherein carrying out the anodic oxidation comprises:
filling the at least one trench with an alkaline liquid;
applying an electric voltage between the alkaline liquid and the substrate.

24. The method of claim 20,
wherein during the anodic oxidation, at least a portion of the p-doped region is exposed to form an electric contact for the anodic oxidation.
